(19) United States
(12) Patent Application Publication
(10) Pub. No.: US 2024/0138216 A1
(43) Pub. Date: Apr. 25, 2024

(54) DISPLAY PANEL

(71) Applicant: Samsung Display Co., Ltd., Yongin-si (KR)

(72) Inventors: SUNGJIN HONG, Yongin-si (KR); Hyewon KIM, Yongin-si (KR); YOOMIN KO, Yongin-si (KR); SUNHO KIM, Yongin-si (KR); JUCHAN PARK, Yongin-si (KR); PILSUK LEE, Yongin-si (KR); CHUNG SOCK CHOI, Yongin-si (KR)

(73) Assignee: Samsung Display Co., Ltd., Yongin-si (KR)

(21) Appl. No.: 18/490,900

(22) Filed: Oct. 19, 2023

(30) Foreign Application Priority Data
Oct. 20, 2022 (KR) 10-2022-0136854

(51) Int. Cl. H10K 59/131; H10K 59/121

(52) U.S. Cl. CPC H10K 59/131; H10K 59/1213

(57) ABSTRACT

A display panel includes first, second, and third emitting parts arranged along a first direction, first, second, and third transistors spaced apart from the first, second, and third emitting parts, and arranged along the first direction, and first, second, and third connection wirings each extending along the first direction and connecting the first, second, and third emitting parts to the first, second, and third transistors. The first, second, and third connection wirings include first, second, and third emission connection parts each connected to a corresponding emitting part, and first, second, and third driver connection parts each connected to a corresponding transistor. An arrangement order of the first, second, and third emission connection parts arranged in the first direction and an arrangement order of the first, second, and third driver connection parts arranged in the first direction are same as each other.

### CROSS-REFERENCE TO RELATED APPLICATION(S)

This application claims priority to and benefits of Korean Patent Application No. 10-2022-0136854 under 35 U.S.C. § 119, filed on Oct. 21, 2022, the entire contents of which are incorporated herein by reference.

### BACKGROUND

### 1. Technical Field

Embodiments relate to a display panel with a narrow bezel region.

### 2. Description of the Related Art

Multimedia electronic devices such as televisions, mobile phones, tablet computers, computers, navigation system units, and game consoles are equipped with a display panel for displaying images.

The display panel includes a light emitting device and a circuit for driving the light emitting device. Emitting parts included in the display panel emit light and generate images according to a voltage applied in the circuit. In order to improve the reliability of the display panel, research is underway on the connection of the light emitting device and the circuit.

### SUMMARY

Embodiments provide a display panel with a reduced bezel region.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display panel may include a first emitting part, a second emitting part, and a third emitting part arranged along a first direction, a first transistor, a second transistor, and a third transistor spaced apart from the first, second, and third emitting parts in the first direction, and arranged along the first direction, and a first connection wiring, a second connection wiring, and a third connection wiring each extending along the first direction and connecting the first, second, and third emitting parts to the first, second, and third transistors, wherein the first, second, and third connection wirings may include a first emission connection part, a second emission connection part, and a third emission connection part each connected to a corresponding emitting part among the first, second, and third emitting parts, and a first driver connection part, a second driver connection part, and a third driver connection part each connected to a corresponding transistor among the first, second, and third transistors, and an arrangement order of the first, second, and third emission connection parts arranged along the first direction and an arrangement order of the first, second, and third driver connection parts arranged along the first direction may be same as each other.

In an embodiment, the first, second, and third emission connection parts may be arranged along the first direction.

In an embodiment, the display panel may further include a fourth emitting part, a fifth emitting part, and a sixth emitting part different from the first, second, and third emitting parts; a fourth transistor, a fifth transistor, and a sixth transistor different from the first, second, and third transistors; a fourth connection wiring, a fifth connection wiring, and a sixth connection wiring spaced apart from the first, second, and third connection wirings in a plan view, and respectively connected to fourth, fifth, and sixth emitting parts different from the first, second, and third emitting parts and to fourth, fifth, and sixth transistors different from the first, second, and third transistors, wherein the fourth, fifth, and sixth connection wirings may include fourth, fifth, and sixth emission connection parts respectively connected to the fourth, fifth, and sixth emitting parts, and fourth, fifth, and sixth driver connection parts respectively connected to the fourth, fifth, and sixth transistors, wherein the fourth, fifth, and sixth emission connection parts may be arranged along the first direction.

In an embodiment, the fourth, fifth, and sixth transistors may be spaced apart from the first, second, and third transistors in the first direction, and the first, second, and third emission connection parts and the fourth, fifth, and sixth emission connection parts may not overlap each other in the first direction.

In an embodiment, the first, second, and third driver connection parts may be arranged along the first direction with the fourth, fifth, and sixth driver connection parts.

In an embodiment, among the first, second, third, fourth, fifth, and sixth connection wirings, the first, second, and third connection wirings may extend in an opposite direction with respect to the fourth, fifth, and sixth connection wirings and driver connection parts.

In an embodiment, an arrangement order in which the first to sixth emission connection parts arranged in the first direction and an arrangement order in which the first, second, third, fourth, fifth, and sixth transistors arranged in the first direction may be same as each other.

In an embodiment, the first, second, and third driver connection parts may be respectively spaced apart from the fourth, fifth, and sixth driver connection parts in a second direction intersecting the first direction.

In an embodiment, light emitted by the first light emitting part and light emitted by the fourth light emitting part may have different colors from each other.

In an embodiment, an arrangement order of the first, second, and third emitting parts and an arrangement order of the fourth, fifth, and sixth emitting parts may be same as each other.

In an embodiment, the display panel may further include a seventh emitting part, an eighth emitting part, and a ninth emitting part spaced apart from the first, second, and third emitting parts in the first direction, a tenth emitting part, an eleventh emitting part, and a twelfth emitting part spaced apart from the fourth, fifth, and sixth emitting parts in the first direction and respectively spaced apart from the seventh, eighth, and ninth emitting parts in the second direction, a seventh transistor, an eighth transistor, and a ninth transistor overlapping the seventh, eighth, and ninth emitting parts in a plan view, respectively connected to the seventh, eighth, and ninth emitting parts, and arranged along the first direction, and a tenth transistor, an eleventh transistor, and a twelfth transistor overlapping the tenth, eleventh, and twelfth emitting parts in a plan view, respectively connected to the tenth, eleventh, and twelfth emitting parts, and arranged along the first direction, wherein the seventh emitting part and the tenth emitting part may emit a same color light.

In an embodiment, the display panel may further include a driving circuit overlapping the first, second, and third emitting parts in a plan view, and providing an electrical signal to each of the first, second, and third emitting parts, wherein the first, second, and third transistors may be spaced apart from the driving circuit.

In an embodiment, each of the first, second, and third emitting parts may include a first electrode, a second electrode disposed on the first electrode, and an emission connection part, and the emission connection part may be connected to the second electrode.

In an embodiment, the second electrodes of the respective first, second, and third emitting parts may be separated from each other, and each of the second electrodes may be a cathode of each of the first, second, and third emitting parts.

In an embodiment, each of the first, second, and third transistors may be an N-type transistor.

In an embodiment, a display panel may include a plurality of pixels including first group pixels and second group pixels, the first and second group pixels including: emitting parts and driving transistors connected to the emitting parts, and a driving circuit that provides an electrical signal to each of the plurality of pixels, and overlaps at least some of the emitting parts the plurality of pixels in a plan view, wherein the emitting parts of the first group pixels may overlap the driving circuit and the emitting parts of the second group pixels are spaced apart from the driving circuit, the first group pixels may include connection wirings including emission connection parts connected to the emitting parts of the first group pixels and driver connection parts connected to the driving transistors of the first group pixels, and an arrangement order of the driving transistors of the first group pixels arranged along a first direction and an arrangement order of the emission connection parts of the first group pixels arranged in the first direction may be same as each other.

In an embodiment, each of the connection wirings of the first group pixels may be disposed in a space between the emission connection parts of the first group pixels and the driver connection parts of the first group pixels.

In an embodiment, each of the connection wirings of the first group pixels may have a multi-layered structure.

In an embodiment, each of the emitting parts of the plurality of pixels may include an anode, a cathode disposed on the anode, and an emitting part disposed between the anode and the cathode, and each of the driving transistors of the plurality of pixels may be connected to the cathode.

In an embodiment, the arrangement order of the driving transistors of the first group pixels arranged in the first direction may be different from each other in adjacent rows.

In an embodiment, an arrangement order of the driving transistors of the second group pixels arranged in the first direction may be different from the arrangement order of the driving transistors of the first group pixels arranged in the first direction.

### BRIEF DESCRIPTION OF THE FIGURES

The accompanying drawings are included to provide a further understanding of the invention, and are incorporated in and form a part of this specification. The drawings illustrate embodiments and, together with the description, serve to explain principles of the invention. In the drawings:

FIG. 1 is a block diagram of a display device according to an embodiment;

FIG. 2A and FIG. 2B are schematic diagrams of equivalent circuits of a pixel according to an embodiment;

FIG. 3A and FIG. 3B are schematic plan views schematically illustrating a display panel according to an embodiment;

FIG. 4A to FIG. 4C are schematic views illustrating a display panel according to an embodiment;

FIG. 5A and FIG. 5B are schematic cross-sectional views of display panels according to an embodiment;

FIG. 6A is a schematic cross-sectional view of an enlarged partial region of a display panel according to an embodiment;

FIG. 6B is a schematic cross-sectional view of a partial region of a display panel according to an embodiment;

FIG. 7 is a schematic view illustrating a display panel according to an embodiment;

FIG. 8A is a schematic plan view illustrating a partial region of a display panel according to an embodiment;

FIG. 8B is a schematic plan view illustrating an enlarged YY′ region illustrated in FIG. 8A;

FIG. 9A is a schematic plan view of a display panel according to an embodiment; and

FIG. 9B is a schematic view illustrating a portion of the display panel illustrated in FIG. 9A.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to the accompanying drawings.

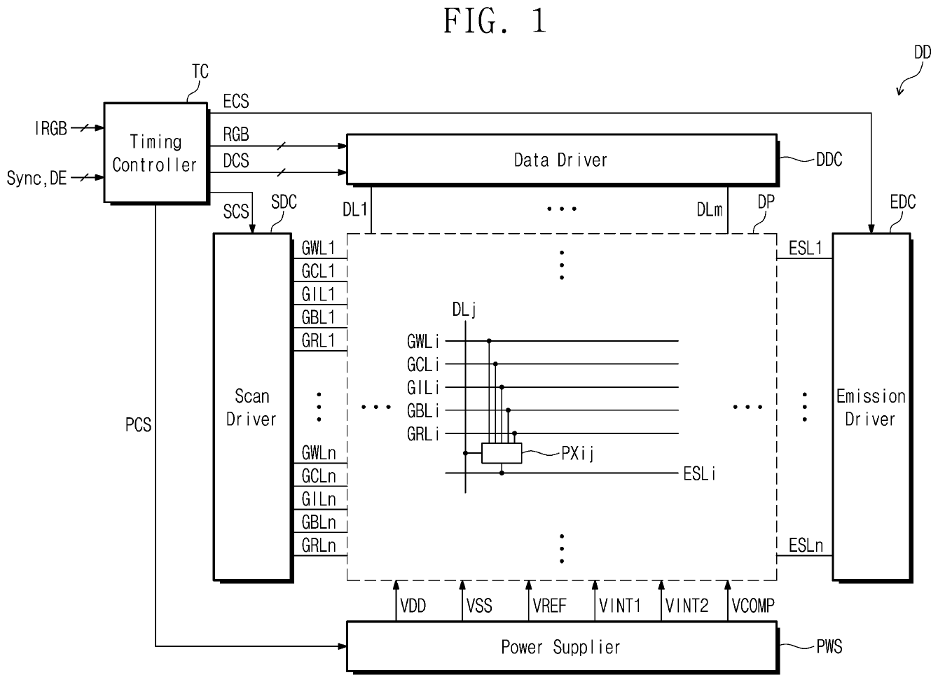

FIG. 1 is a block diagram of a display device according to an embodiment. Referring to FIG. 1, a display device DD may include a display panel DP, panel drivers SDC, EDC, and DDC, a power supplier PWS, and a timing controller TC. In an embodiment, the display panel DP will be described as being a light emitting type display panel. The light emitting type display panel DP may include an organic light emitting display panel, an inorganic light emitting display panel, or a quantum dot light emitting display panel. In the following embodiment to be described, an organic light emitting display panel will be described in detail as an example. The panel drivers may include a scan driver SDC, an emission driver EDC, and a data driver DDC.

The display panel DP may include scan lines GWL1 to GWLn, GCL1 to GCLn, GILL to GILn, GBL1 to GBLn, and GRL1 to GRLn, emission lines ESL1 to ESLn, and data lines DL1 to DLm. The display panel DP may include pixels connected to the scan lines GWL1 to GWLn, GCL1 to GCLn, GILL to GILn, GBL1 to GBLn, and GRL1 to GRLn, emission lines ESL1 to ESLn, and data lines DL1 to DLm. Here, m and n are integers greater than 1.

For example, a pixel PXij positioned at an i-th horizontal line (or an i-th pixel row) and a j-th vertical line (or a j-th pixel column) may be connected to an i-th first scan line GWLi (or a write scan line), an i-th second scan line GCLi (or a compensation scan line), an i-th third scan line GILi (or a first initialization scan line), an i-th fourth scan line GBLi (or a second initialization scan line), an i-th fifth scan line GRLi (or a reset scan line), a j-th data line DLj, and an i-th emission line ESLi. Here, i and j are integers greater than 1.

The pixel PXij may include light emitting devices, transistors, and capacitors. The pixel PXij may be supplied with a first power voltage VDD, a second power voltage VSS, a third power voltage VREF (or a reference voltage), a fourth power voltage VINT1 (or a first initialization voltage), a fifth power voltage VINT2 (or a second initialization voltage), and a sixth power voltage VCOMP (or a compensation voltage) through the power supplier PWS.

The voltage values of the first power voltage VDD and the second power voltage VSS may be set such that a current may flow in the light emitting device to emit light. For example, the first power voltage VDD may be set to a voltage higher than the second power voltage VSS.

The third power voltage VREF may be a voltage for initializing a gate of a driving transistor included in the pixel PXij. The third power voltage VREF may be used to implement a predetermined gray scale by using a voltage difference with a data signal. To this end, the third power voltage VREF may be set to a predetermined voltage within a voltage range of the data signal.

The fourth power voltage VINT1 may be a voltage for initializing a capacitor included in the pixel PXij. The fourth power voltage VINT1 may be set to a voltage lower than the third power voltage VREF. For example, the fourth power voltage VINT1 may be set to a voltage lower than a difference between the third power voltage VREF and a threshold voltage of the driving transistor. However, embodiments are not limited thereto.

The fifth power voltage VINT2 may be a voltage for initializing a cathode of a light emitting device included in the pixel PXij. The fifth power voltage VINT2 may be set to a voltage lower than the first power voltage VDD or the fourth power voltage VINT1 or may be set to a voltage similar to or the same as the third power voltage VREF, but embodiments are not limited thereto, and the fifth power voltage VINT2 may be set to a voltage similar to or the same as the first power voltage VDD.

The sixth power voltage VCOMP may supply a predetermined current to the driving transistor in case that the threshold voltage of the driving transistor is compensated.

FIG. 1 illustrates that the first to sixth power voltages VDD, VSS, VREF, VINT1, VINT2, and VCOMP are all supplied from the power supplier PWS, but embodiments are not limited thereto. For example, the first power voltage VDD and the second power voltage VSS may be all supplied regardless of a structure of the pixel PXij, and at least one of the third power voltage VREF, the fourth power voltage VINT1, the fifth power voltage VINT2, and the sixth power voltage VCOMP may not be supplied in correspondence to the structure of the pixel PXij.

In an embodiment, signal lines connected to the pixel PXij may be variously set in correspondence to a circuit structure of the pixel PXij.

The scan driver SDC may receive a first control signal SCS from the timing controller TC, and may supply a scan signal to each of the first scan lines GWL1 to GWLn, the second scan lines GCL1 to GCLn, the third scan lines GILL to GILn, the fourth scan lines GBL1 to GBLn, and the fifth scan lines GRL1 to GRLn based on the first control signal SCS.

The scan signal may be set to a voltage at which transistors which are supplied with the scan signal are turned on. For example, a scan signal supplied to a P-type transistor may be set to a logic low level, and a scan signal supplied to an N-type transistor may be set to a logic high level. Hereinafter, the meaning of “a scan signal is supplied” may be understood as that a scan signal is supplied at a logic level which turns on a transistor controlled by the scan signal.

In FIG. 1, for convenience of description, the scan driver SDC is illustrated as having a single configuration, but embodiments are not limited thereto. According to an embodiment, scan drivers may be included to supply a scan signal to each of the first scan lines GWL1 to GWLn, the second scan lines GCL1 to GCLn, the third scan lines GILL to GILn, the fourth scan lines GBL1 to GBLn, and the fifth scan lines GRL1 to GRLn.

The emission driver EDC may supply an emission signal to the emission lines ESL1 to ESLn based on a second control signal ECS. For example, the emission signal may be supplied sequentially to the emission lines ESL1 to ESLn.

Transistors connected to the emission lines ESL1 to ESLn according to an embodiment may be configured as N-type transistors. For example, the emission signal supplied to the emission lines ESL1 to ESLn may be set to a gate-off voltage. Transistors receiving an emission signal may be turned off in case that the emission signal is supplied, and may be set to the state of being turned-on otherwise.

The second control signal ECS may include an emission start signal and clock signals, and the emission driver EDC may be implemented as a shift register which sequentially shifts the emission start signal in a pulse form using the clock signals so as to sequentially generate and output an emission signal in a pulse form.

The data driver DDC may receive a third control signal DCS and image data RGB from the timing controller TC. The data driver DDC may convert the image data RGB in a digital form into an analog data signal (e.g., a data signal). The data driver DDC may supply a data signal to the data lines DL1 to DLm in correspondence to the third control signal DCS.

The third control signal DCS may include a data enable signal, a horizontal start signal, a data clock signal, and the like, which indicate the output of a valid data signal. For example, the data driver DDC may include a shift register that shifts a horizontal start signal in synchronization with a data clock signal to generate a sampling signal, a latch that latches the image data RGB in response to the sampling signal, a digital-to-analog converter (or a decoder) that converts the latched image data (e.g., data in a digital form) into data signals in an analog form, and buffers (or amplifiers) that output the data signals to the data lines DL1 to DLm.

The power supplier PWS may supply the first power voltage VDD, the second power voltage VSS, and the third power voltage VREF for driving the pixel PXij to the display panel DP. For example, the power supplier PWS may supply at least one voltage among the fourth power voltage VINT1, the fifth power voltage VINT2, and the sixth power voltage VCOMP to the display panel DP.

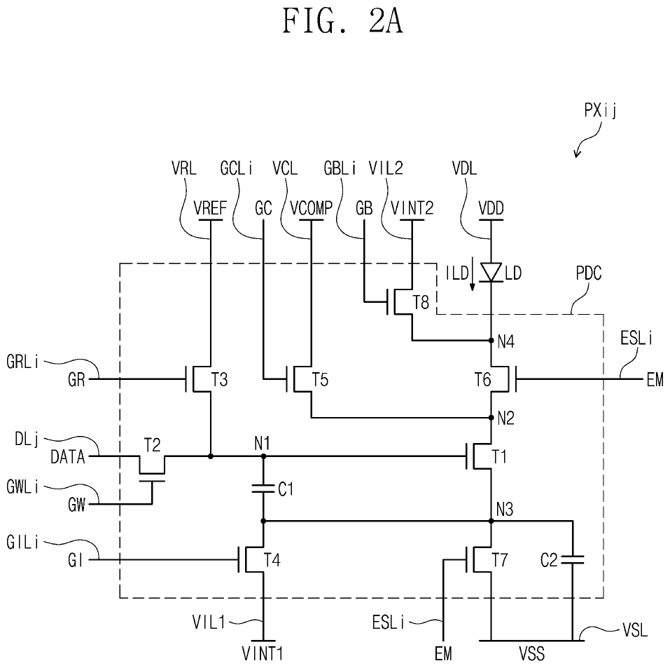

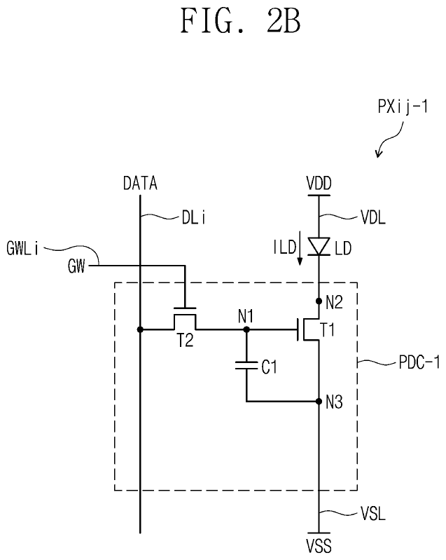

As an example, the power supplier PWS may respectively supply the first power voltage VDD, the second power voltage VSS, the third power voltage VREF, the fourth power voltage VINT1, the fifth power voltage VINT2, and the sixth power voltage VCOMP to the display panel DP via a first power line VDL in, e.g., FIG. 2A, a second power line VSL (see FIG. 2A), a third power line VRL (or a reference voltage line) in, e.g., FIG. 2A, a fourth power line VIL1 (or a first initialization voltage line) in, e.g., FIG. 2A, a fifth power line VIL2 (or a second initialization voltage line) in, e.g., FIG. 2A, a sixth power line VCL (or a compensation voltage line) in, e.g., FIG. 2A.

The power supplier PWS may be implemented as a power management integrated circuit, but embodiments are not limited thereto.

The timing controller TC may generate the first control signal SCS, the second control signal ECS, the third control signal DCS, and a fourth control signal PCS based on input image data IRGB, a synchronization signal Sync (e.g., a vertical synchronization signal, a horizontal synchronization signal, etc.), a data enable signal DE, a clock signal, etc. The first control signal SCS may be supplied to the scan driver SDC, the second control signal ECS may be supplied to the emission driver EDC, the third control signal DCS may be supplied to the data driver DDC, and the fourth control signal PCS may be supplied to the power supplier PWS. The timing controller TC may generate the image data RGB (or frame data) by rearranging the input image data IRGB in correspondence to an arrangement of the pixel PXij in the display panel DP.

For example, the scan driver SDC, the emission driver EDC, the data driver DDC, the power supplier PWS, and/or the timing controller TC may be formed (e.g., directly formed) on the display panel DP, or may be provided in the form of a separate driving chip and be connected to the display panel DP. For example, at least two among the scan driver SDC, the emission driver EDC, the data driver DDC, the power supplier PWS, and the timing controller TC may be provided as a single driving chip. For example, the data driver DDC and the timing controller TC may be provided as a single driving chip.

In the above, the display device DD according to an embodiment has been described with reference to FIG. 1, but embodiments are not limited thereto. Signal lines may be further added or omitted according to the configuration of a pixel. For example, the connection relationship between a single pixel and signal lines may be changed. In case that any one of the signal lines is omitted, another signal line may replace the omitted signal line.

FIG. 2A and FIG. 2B are schematic diagram of equivalent circuits of a pixel according to an embodiment. FIG. 2A and FIG. 2B illustrate equivalent circuit diagrams of pixels PXij and PXij-1 connected to the i-th first scan line GWLi (hereinafter, a first scan line) and connected to the j-th data line DLj (hereinafter, a data line).

As illustrated in FIG. 2A, the pixel PXij may include a light emitting device LD and a pixel driver PDC. The light emitting device LD may be connected to the first power line VDL and to the pixel driver PDC.

The pixel driver PDC may be connected to the scan lines GWLi, GCLi, GILi, GBLi, and GRLi, the data line DLj, the emission line ESLi, and the power voltage lines VDL, VSL, VIL1, VIL2, VRL, and VCL. The pixel driver PDC may include first to eighth transistors Ti, T2, T3, T4, T5, T6, T7, and T8, a first capacitor C1, and a second capacitor C2. Hereinafter, a case in which each of the first to eighth transistors T1, T2, T3, T4, T5, T6, T7, and T8 is an N-type transistor will be described as an example. However, embodiments are not limited thereto, and some of the first to eighth transistors T1 to T8 may be N-type transistors, and the remaining transistors thereof may be P-type transistors, or each of the first to eighth transistors T1 to T8 may be a P-type transistor, and embodiments are not limited to any one embodiment.

A gate of the first transistor T1 may be connected to a first node Ni. A first electrode of the first transistor T1 may be connected to a second node N2, and a second electrode thereof may be connected to a third node N3. The first transistor T1 may be a driving transistor. The first transistor T1 may control a driving current ILD flowing from the first power line VDL to the second power line VSL via the light emitting device LD in correspondence to a voltage of the first node Ni. For example, the first power voltage VDD may be set to a voltage having a potential higher than that of the second power voltage VS S.

In the description, “being electrically connected between a transistor and a signal line or between a transistor and a transistor” means that “a source, a drain, and a gate of the transistor have a shape of a single body with the signal line, or are connected through a connection electrode.”

The second transistor T2 may include a gate connected to the write scan line GWLi, a first electrode connected to the data line DLj, and a second electrode connected to the first node Ni. The second transistor T2 may supply a data signal DATA to the first node N1 in response to a write scan signal GW transmitted through the write scan line GWLi. The second transistor T2 may be turned on in case that the write scan signal GW is supplied to the write scan line GWLi and electrically connect the data line DLj and the first node Ni.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node Ni. In an embodiment, a gate of the third transistor T3 may receive a reset scan signal GR through the i-th fifth scan line GRLi (hereinafter, a fifth scan line). The third transistor T3 may be turned on in case that the reset scan signal GR is supplied to the reset scan line GRLi and provide the reference voltage VREF to the first node Ni.

The fourth transistor T4 may be connected between the third node N3 and the first initialization voltage line VIII. A first electrode of the fourth transistor T4 may be connected to the third node N3, and a second electrode of the fourth transistor T4 may be connected to a first initialization voltage line VIL1 which provides the first initialization voltage VINT1. The fourth transistor T4 may be referred to as a first initialization transistor. A gate of the fourth transistor T4 may receive a first initialization scan signal GI through the i-th third scan line GILi (hereinafter, a third scan line). The fourth transistor T4 may be turned on in case that the first initialization scan signal GI is supplied to the first initialization scan line GILi and supply the first initialization voltage VINT1 to the third node N3.

The fifth transistor T5 may be connected between the compensation power line VCL and the second node N2. A first electrode of the fifth transistor T5 may receive the compensation voltage VCOMP through the compensation voltage line VCL, and a second electrode of the fifth transistor T5 may be connected to the second node N2 to be electrically connected to the first electrode of the first transistor Ti. A gate of the fifth transistor T5 may receive a compensation scan signal GC through the i-th second scan line GCLi (hereinafter, a second scan line). The fifth transistor T5 may be turned on in case that the compensation scan signal GC is supplied to the compensation scan line GCLi and provide the compensation voltage VCOMP to the second node N2, and during a compensation period, a threshold voltage of the first transistor T1 may be compensated.

The sixth transistor T6 may be connected between the first transistor T1 and the light emitting device LD. For example, a gate of the sixth transistor T6 may receive an emission signal EM through the i-th emission line ESLi (hereinafter, an emission line). A first electrode of the sixth transistor T6 may be connected to a cathode of the light emitting device LD through a fourth node N4, and a second electrode of the sixth transistor T6 may be connected to the first electrode of the first transistor T1 through the second node N2. The sixth transistor T6 may be referred to as a first emission control transistor. The sixth transistor T6 may be turned on in case that the emission signal EM is supplied to the emission line ESLi, and electrically connect the light emitting device LD and the first transistor T1.

The seventh transistor T7 may be connected between the second power line VSL and the third node N3. A first electrode of the seventh transistor T7 may be connected to the second electrode of the first transistor T1 through the third node N3, and a second electrode of the seventh transistor T7 may receive the second power voltage VSS through the second power line VSL. A gate of the seventh transistor T7 may be electrically connected to the emission line ESLi. The seventh transistor T7 may be referred to as a second emission control transistor. The seventh transistor T7 may be turned on in case that the emission signal EM is supplied to the emission line ESLi, and electrically connect the second electrode of the first transistor T1 and the second power line VSL.

In an embodiment, the sixth transistor T6 and the seventh transistor T7 are illustrated as being connected to the same emission line ESLi and turned on through the same emission signal EM, but this is an example, and the sixth transistor T6 and the seventh transistor T7 may be independently turned on by different signals distinguished from each other. For example, in the pixel driver PDC according to an embodiment, one of the sixth transistor T6 and the seventh transistor T7 may be omitted.

The eighth transistor T8 may be connected between the second initialization voltage line VIL2 and the fourth node N4. For example, the eighth transistor T8 may include a gate connected to the i-th fourth scan line GBLi (hereinafter, a fourth scan line), a first electrode connected to the second initialization voltage line VIL2, and a second electrode connected to the fourth node N4. The eighth transistor T8 may be referred to as a second initialization transistor. The eighth transistor T8 may supply the second initialization voltage VINT2 to the fourth node N4 corresponding to the cathode of the light emitting device LD in response to a second initialization scan signal GB transmitted through the second initialization scan line GBLi. The cathode of the light emitting device LD may be initialized by the second initialization voltage VINT2.

In an embodiment, some of the second to eighth transistors T2, T3, T4, T5, T6, T7, and T8 may be simultaneously turned on through the same scan signal. For example, the eighth transistor T8 and the fifth transistor T5 may be simultaneously turned on by the same scan signal. For example, the eighth transistor T8 and the fifth transistor T5 may be operated by the same compensation scan signal GC. The eighth transistor T8 and the fifth transistor T5 may be simultaneously turned on/off by the same compensation scan signal GC. For example, the compensation scan line GCLi and the second initialization scan line GBLi may be provided as substantially a single scan line. Accordingly, the initialization of the cathode of the light emitting device LD and the compensation for the threshold voltage of the first transistor T1 may be performed at the same timing. However, this is an example, and embodiments are not limited thereto.

For example, according to an embodiment, the initialization of the cathode of the light emitting device LD and the compensation for the threshold voltage of the first transistor T1 may be performed by using the same power voltage. For example, the compensation voltage line VCL and the second initialization voltage line VIL2 may be provided as substantially a single power voltage line. For example, since the initialization operation of a cathode and the compensation operation of a driving transistor may be performed with a power voltage, the design of a driver may be simplified. However, this is an example, and embodiments are not limited to any one embodiment.

The first capacitor C1 may be disposed between the first node N1 and the third node N3. The first capacitor C1 may store a difference voltage between the first node N1 and the third node N3. The first transistor CI may be referred to as a storage capacitor.

The second capacitor C2 may be disposed between the third node N3 and the second power line VSL. For example, an electrode of the second capacitor C2 may be connected to the second power line VSL which is supplied with the second power voltage VSS, and another electrode of the second capacitor C2 may be connected to the third node N3. The second capacitor C2 may store a charge corresponding to a voltage difference between the second power voltage VSS and the second node N2. The second transistor C2 may be referred to as a hold capacitor. The second capacitor C2 may have a higher storage capacity as compared to the first capacitor C1. Accordingly, the second capacitor C2 may minimize a voltage change of the third node N3 in correspondence to a voltage change of the first node Ni.

In an embodiment, the light emitting device LD may be connected to the pixel driver PDC through the fourth node N4. The light emitting device LD may include an anode connected to the first power line VDL and a cathode facing (or opposite to) the anode. In an embodiment, the light emitting device LD may be connected to the pixel driver PDC through the cathode. For example, in the pixel PXij, a connection node to which the light emitting device LD and the pixel driver PDC are connected may be the fourth node N4, and the fourth node N4 may correspond to a connection node between the first electrode of the sixth transistor T6 and the cathode of the light emitting device LD. Accordingly, the potential of the fourth node N4 may substantially correspond to the potential of the cathode of the light emitting device LD.

For example, the anode of the light emitting device LD may be connected to the first power line VDL and applied with the first power voltage VDD, which is a constant voltage, and the cathode thereof may be connected to the first transistor T1 though the sixth transistor T6. For example, in an embodiment in which the first to eighth transistors T1 to T8 are N-type transistors, the potential of the third node N3 corresponding to a source of the first transistor T1, which is a driving transistor, may not be directly affected by the characteristics of the light emitting device LD. Therefore, although the light emitting device LD is deteriorated, the influence on transistors forming the pixel driver PDC, e.g., a gate-source voltage Vgs of a driving transistor, may be reduced. For example, since an amount of change in driving current due to the deterioration of the light emitting device LD may be reduced, afterimage defects of the display panel due to an increase in usage time may be reduced and the lifespan thereof may be improved.

In another example, as illustrated in FIG. 2B, the pixel PXij-1 may include a pixel driver PDC-1 including two transistors T1 and T2 and one capacitor C1. The pixel driver PDC-1 may be connected to a light emitting device LD, a write scan line GWLi, a data line DLj, and a second power line VSL. The pixel driver PDC-1 illustrated in FIG. 2B may correspond to the pixel driver illustrated in FIG. 2A from which the third to eighth transistors T3 to T8 and the second capacitor C2 are omitted.

Each of the first and second transistors T1 and T2 may be an N-type transistor or a P-type transistor. In an embodiment, each of the first and second transistors T1 and T2 is described as an N-type transistor.

The first transistor T1 may include a gate connected to a first node N1, a first electrode connected to a second node N2, and a second electrode connected to a third node N3. The second node N2 may be a node connected to the side of a first power line VDL, and the third node N3 may be a node connected to the side of a second power line VSL. The first transistor Ti may be connected to the light emitting device LD through the second node N2 and connected to the second power line VSL through the third node N3. The first transistor T1 may be a driving transistor.

The second transistor T2 may include a gate receiving a write scan signal GW through the write scan line GWLi, a first electrode connected to the data line DLj, and a second electrode connected to the first node N1. The second transistor T2 may supply a data signal DATA to the first node N1 in response to a write scan signal GW transmitted through the write scan line GWLi.

The capacitor C1 may include an electrode connected to the first node N1 and an electrode connected to the third node N3. The capacitor C1 may store the data signal DATA transmitted to the first node Ni.

The light emitting device LD may include an anode and a cathode. In an embodiment, the anode of the light emitting device LD may be connected to the first voltage line VDL, and the cathode thereof may be connected to the pixel driver PDC-1 through the second node N2. In an embodiment, the cathode of the light emitting device LD may be connected to the first transistor T1. The light emitting device LD may emit light in correspondence to an amount of current flowing in the first transistor T1 of the pixel driver PDC-1.

In an embodiment in which the first and second transistors T1 and T2 are N-type transistors, the second node N2 to which the cathode of the light emitting device LD and the pixel driver PDC-1 are connected may correspond to a drain of the first transistor T1. For example, a change in the gate-source voltage Vgs of the first transistor T1 due to the light emitting device LD may be prevented. Accordingly, since an amount of change in driving current due to the deterioration of the light emitting device LD may be reduced, afterimage defects of the display panel due to an increase in usage time may be reduced and the lifespan thereof may be improved.

FIG. 2A and FIG. 2B illustrate circuits for the pixel drivers PDC and PDC-1 according to an embodiment, and as long as a display panel according to an embodiment is a circuit connected to the cathode of the light emitting device LD, the number or arrangement relationship of transistors and the number or arrangement relationship of capacitors may be designed in various ways and are not limited to any one embodiment.

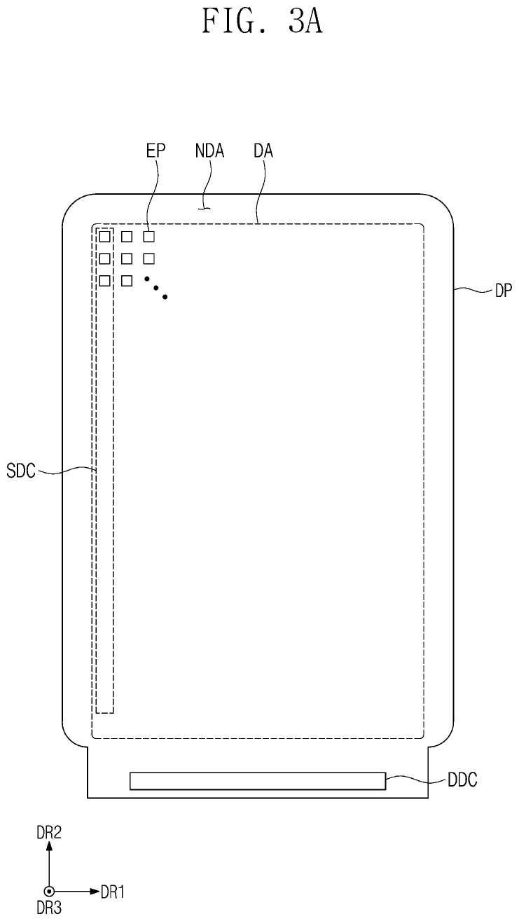

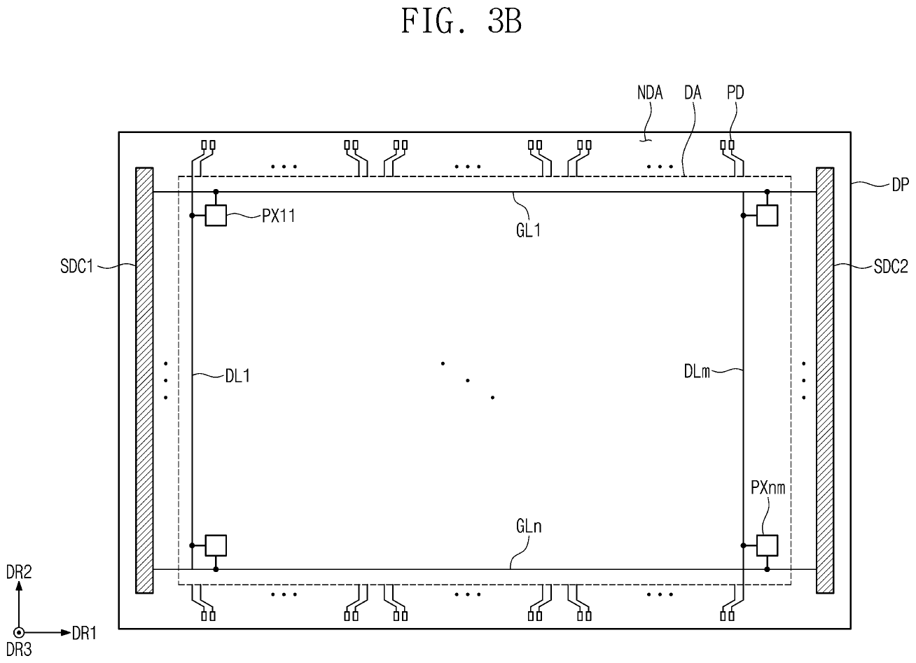

FIG. 3A and FIG. 3B are schematic plan views schematically illustrating a display panel according to an embodiment. In each of FIG. 3A and FIG. 3B, some components are omitted. Hereinafter, an embodiment will be described with reference to FIG. 3A and FIG. 3B. Referring to FIG. 3A, the display panel DP of an embodiment may be divided into a display region DA and a peripheral region NDA (or a non-display region). The display region DA may include emitting parts EP.

The emitting parts EP may be regions each emitting light by the pixels PXij (see FIG. 1). For example, each of the emitting parts EP may correspond to a light emitting opening OP-PDL to be described below.

The peripheral region NDA may be disposed adjacent to the display region DA. In an embodiment, the peripheral region NDA may have a shape surrounding the display region DA. However, this is an example, and the peripheral region NDA may be disposed on a side of the display region DA, or may be omitted, and is not limited to any one embodiment.

In an embodiment, the scan driver SDC and the data driver DDC may be mounted on the display panel DP. In an embodiment, the scan driver SDC may be disposed in the display region DA, and the data driver DDC may be disposed in the peripheral region NDA. The scan driver SDC may overlap at least some of the emitting parts EP disposed in the display region DA in a plan view. Since the scan driver SDC is disposed in the display region DA, the area of the peripheral area NDA may be reduced as compared to a typical display panel in which a scan driver is disposed in a peripheral region, and a display device with a thin bezel may be readily implemented.

Unlike what is illustrated in FIG. 3A, the scan driver SDC may be provided as two portions separated from each other. The two scan drivers SDC may be disposed in left and right sides of the display panel DP, and may be spaced apart from each other by the center area of the display region DA between the left and right sides of the display region DA. In another example, the scan driver SDC may be provided in a number equal to or greater than 2, and is not limited to any one embodiment.

FIG. 3A illustrates an example of a display panel, and the data driver DDC may be disposed in the display region DA. For example, some of the emitting parts EP disposed in the display region DA may overlap the data driver DDC in a plan view.

In an embodiment, the data driver DDC may be provided in the form of a separate driving chip independent from the display panel DP and be connected to the display panel DP. However, this is an example, and the data driver DDC and the scan driver SDC may be formed in a same process for forming the display panel DP, and is not limited to any one embodiment.

As illustrated in FIG. 3B, the display panel DP may have a shape in which a length extending in a first direction DR1 is longer than a length extending in a second direction DR2. In an embodiment, the display panel DP may include scan drivers SDC1 and SDC2. The scan drivers SDC1 and SDC2 may include a first scan driver SDC1 and a second scan driver SDC2 spaced apart from each other in the first direction DR1.

The first scan driver SDC1 may be connected some of scan lines GL1 to GLn, and the second scan driver SDC2 may be connected others of the scan lines GL1 to GLn. For example, the first scan driver SDC1 may be connected odd-numbered scan lines among the scan lines GL1 to GLn, and the second scan driver SDC2 may be connected even-numbered scan lines among the scan lines GL1 to GLn.

For convenience of description, FIG. 3B illustrates pads PD of the data lines DL1 to DLm. The pads PD may be defined at end portions of the data lines DL1 to DLm. The data lines DL1 to DLm may be connected to the data driver DDC (see FIG. 3A) through the pads PD. For example, the pixel PX11 may be connected to the scan line GL1 and the date line DL1, and the pixel PXnm may be connected to the scan line GLn and the data line DLm.

According to an embodiment, the pads PD may be divided and arranged at positions spaced apart from each other by the display region DA disposed between the pads PD in the peripheral region NDA. For example, some of the pads PD may be disposed on an upper side, for example, a side adjacent to the first scan line GL1 among the scan lines GL1 to GLn, and others of the pads PD may be disposed on a lower side, e.g., a side adjacent to the last scan line GLn among the scan lines GL1 to GLn. In an embodiment, pads PD connected to odd-numbered data lines among the data lines DL1 to DLm may be disposed on an upper side, and pads PD connected to even-numbered data lines among the data lines DL1 to DLm may be disposed on a lower side.

For example, the display panel PD may include upper data drivers connected to the pads PD disposed on the upper side and/or lower data drivers connected to the pads PD disposed on the lower side. However, this is an example, and the display panel PD may include an upper data driver connected to the pads PD disposed on the upper side and/or one lower data driver connected to the pads PD disposed on the lower side. For example, the pads PD according to an embodiment may be disposed on a single side of the display panel DP and connected to a single data driver, and is not limited any one embodiment.

For example, as described above with reference to FIG. 3A, even in the display panel DP in FIG. 3B, a scan driver and/or a data driver may be disposed in the display region DA, and accordingly, some of the emitting parts disposed in the display regions DA may overlap the scan driver and/or the data driver in a plan view.

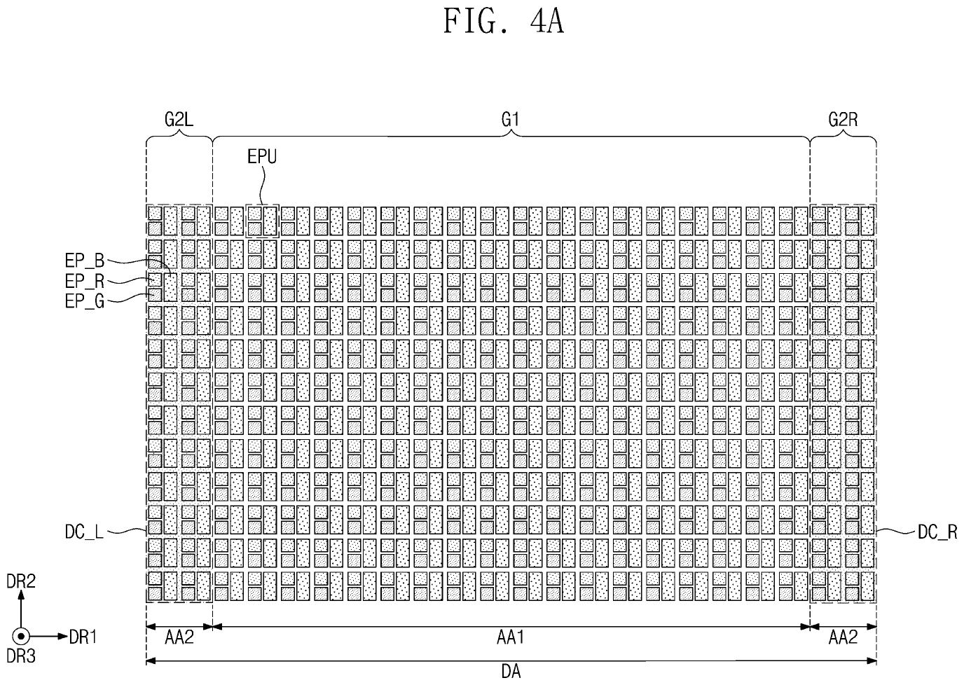

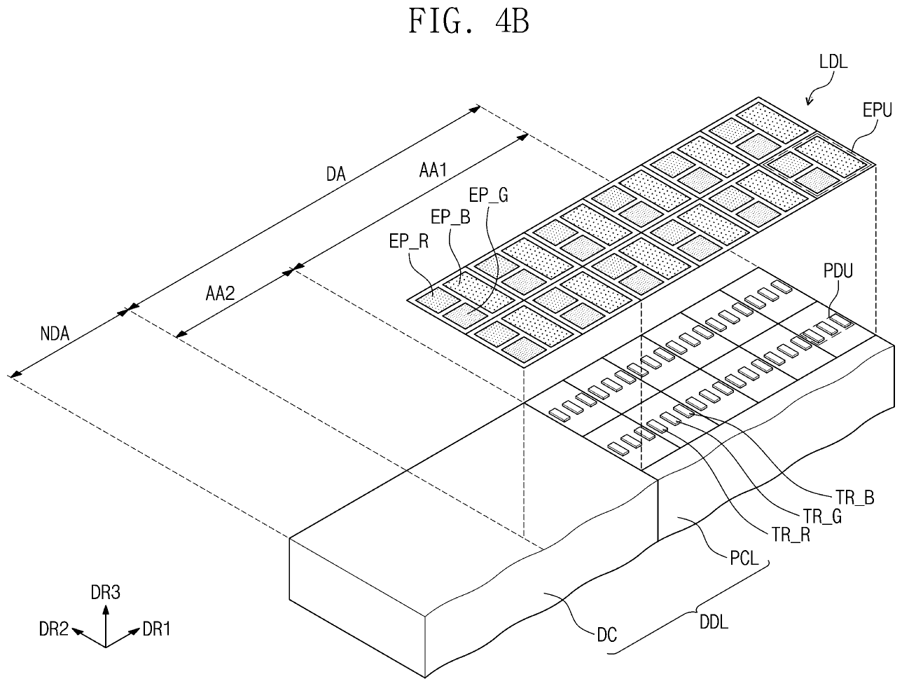

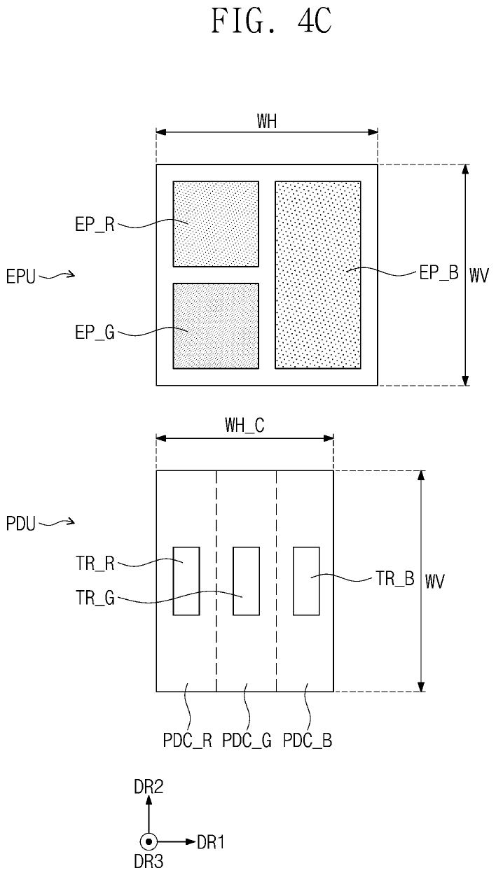

FIG. 4A to FIG. 4C are schematic views illustrating a display panel according to an embodiment. FIG. 4A is a schematic plan view schematically illustrating the display region DA, and FIG. 4B is a schematic perspective view schematically illustrating the display panel. FIG. 4C is a schematic plan view schematically illustrating a portion of the display panel. Hereinafter, with reference to FIG. 4A to FIG. 4C, an embodiment will be described.

Referring to FIG. 4A and FIG. 4B, a driving circuit DC may overlap both the display region DA and the peripheral region NDA. For example, the driving circuit DC may partially overlap the emitting parts EP. The driving circuit DC may correspond to the above-described scan drivers SDC, SDC1, and SDC2, but embodiments are not limited thereto. This is an example, and as illustrated in FIG. 2A, the driving circuit DC may be spaced apart from the peripheral region NDA and be all disposed in the display region DA, e.g., may entirely overlap the emitting parts EP, and is not limited to any one embodiment.

The driving circuit DC may be provided in plurality. In an embodiment, the driving circuit DC may include a first driving circuit DC_L and a second driving circuit DC_R spaced apart from each other in the first direction DR1. The first driving circuit DC_L and the second driving circuit DC_R may be the same circuit. For example, the first driving circuit DC_L may be a scan driving circuit for providing scan signals to odd-numbered pixel rows, and the second driving circuit DC_R may be a scan driving circuit for providing scan signals to odd-numbered pixel rows. In another example, the first driving circuit DC_L and the second driving circuit DC_R may be different circuits from each other. For example, the first driving circuit DC_L may be a scan driving circuit for providing scan signals to each pixel row and the second driving circuit DC_R may be an emission control driving circuit for providing emission control signals to each pixel row. The driving circuit DC according to an embodiment may be provided in various forms, and is not limited to any one embodiment.

The display region DA may be divided into a first region AA1 and a second region AA2. The first region AA1 may be a region not overlapping the driving circuits DC_L and DC_R, and the second region AA2 may be a region overlapping each of the driving circuits DC_L and DC_R. Since the display panel 100 may include the driving circuits DC_L and DC_R, the second region AA2 may be provided in plurality and defined at positions spaced apart from each other by the first region AA1 interposed therebetween in the first direction DR1.

The emitting parts EP may be divided into a plurality of groups according to regions in which the emitting parts EP are disposed. For example, the emitting parts EP may be divided into a main group G1 disposed in the first region AA1, a first group G2L overlapping the first driving circuit DC_L, and a second group G2R overlapping the second driving circuit DC_R. The first group G2L and the second group G2R may be emitting parts disposed at positions spaced apart from each other, and the main group G1 may be disposed between the first group G2L and the second group G2R in the first direction DR1.

Among the emitting parts ED, a first emitting part EP_R that emits a first light, a second emitting part EP_G that emits a second light, and a third emitting part EP_B that emits a third light may form a light emitting unit EPU. In an embodiment, the single light emitting unit EPU may correspond to a pixel, and the first to third emitting parts EP_R, EP_G, and EP_B may each correspond to a sub pixel, but embodiments are not limited thereto.

In FIG. 4B, a light emitting device layer LDL including the light emitting units EPU and a driving device layer DDL including pixel driving units PDU are separately illustrated, and for convenience of description, light emitting units EPU in 2 rows and 6 columns and corresponding pixel driving units PDU in 2 rows and 6 columns are illustrated.

Each of the light emitting units EPU may include at least one light element. The light emitting units EPU may form the light emitting device layer LDL. The driving device layer DDL may be disposed below the light emitting device layer LDL. The driving device layer DDL may include a driving circuit DC and a pixel driving circuit PCL. As described above, the driving circuit DC may include driving elements that drive the display region DA, such as the scan driver SDC, SDC1, or SDC2, or the data driver DDC. The pixel driving circuit PCL may include pixel driving units PDU composed of driving elements that respectively drive the light emitting units EPU.

The pixel driving units PDU may be connected to corresponding light emitting units EPU among the light emitting units EPU and may drive the connected light emitting units EPU. The pixel driving units PDU may be disposed in the display region DA. The pixel driving units PDU may each include pixel drivers PDC_R, PDC_G, and PDC_B which are respectively connected to the emitting parts EP_R, EP_G, and EP_B. The pixel drivers PDC_R, PDC_G, and PDC_B may respectively include connection transistors TR_R, TR_G, and TR_B. The connection transistors TR_R, TR_G, and TR_B may be transistors respectively connected to corresponding emitting parts EP_R, EP_G, and EP_B in the pixel drivers PDC_R, PDC_G, and PDC_B. For example, in case that the pixel driver PDC_R is composed of the pixel driver PDC (see FIG. 2A) illustrated in FIG. 2A, the connection transistor TR_R connected thereto may correspond to the sixth transistor T6 (see FIG. 2A) having the light emitting device LD (see FIG. 2A) and the connection node N4 (see FIG. 2A). In another example, for example, in case that the pixel driver PDC_R is composed of the pixel driver PDC-1 (see FIG. 2B) illustrated in FIG. 2B, the connection transistor TR_R connected thereto may correspond to the first transistor T1 (see FIG. 2B) having the light emitting device LD and the second node N2 (see FIG. 2B). The connection transistors TR_R, TR_G, and TR_B may be provided in various forms as long as they are connected to corresponding emitting parts EP_R, EP_G, and EP_B, and are not limited to any one embodiment.

Among the light emitting units EPU, a light emitting unit EPU disposed in the second region AA2, e.g., the emitting parts of the first group G2L, may overlap the driving circuit DC and may not overlap the pixel driving units PDU in a plan view. Among the light emitting units EPU, a light emitting unit EPU disposed in the first region AA1, e.g., the emitting parts of the main group G1, may be spaced apart from the driving circuit DC and may overlap the pixel driving units PDU in a plan view.

FIG. 4C illustrates a light emitting unit EPU and a pixel driving unit PDU connected thereto. In the light emitting unit EPU, the first emitting part EP_R and the second emitting part EP_G may be arranged along a direction parallel to the second direction DR2, and the third emitting part EP_B may be disposed at a position in the first direction DR1 with respect to each of the first emitting part EP_R and the second emitting part EP_G. In an embodiment, the third emitting part EP_B may be adjacent to each of the first emitting part EP_R and the second emitting part EP_G in the first direction DR1. For example, shapes or arrangements of the first to third emitting parts EP_R, EP_G, and EP_B, or the number of emitting parts forming the light emitting unit EPU may be variously selected, and are not limited to any one embodiment.

The pixel driving unit PDU may include first to third pixel drivers PDC_R, PDC_G, and PDC_B respectively driving the first to third emitters EP_R, EP_G, and EP_B. The first to third pixel drivers PDC_R, PDC_G, and PDC_B may be arranged along the first direction DR1. The first to third pixel drivers PDC_R, PDC_G, and PDC_B may include the first to third connection transistors TR_R, TR_G, and TR_B respectively connected to the first to third emitting parts EP_R, EP_G, and EP_B. Each of the first to third connection transistors TR_R, TR_G, and TR_B may be a driving transistor, but embodiments are not limited thereto. For example, the pixels (e.g., PXij in FIG. 2A or PXij-1 in FIG. 2B) may include first group pixels and second group pixels. For example, the first group pixels and the second group pixels may include the emitting parts EP (e.g., the first to third emitting parts EP_R, EP_G, and EP_B) and driving transistors (e.g., the first to third connection transistors TR_R, TR_G, and TR_B), which are connected to the emitting parts EP and drive the emitting parts EP. For example, the emitting parts EP of the first group pixels may overlap the first driving circuit DC_L or the second driving circuit DC_R and may be disposed in the second region AA2. The emitting parts EP of the second group pixels may be spaced apart from the first driving circuit DC_L or the second driving circuit DC_R and may be disposed in the first region AA1. For example, the driving transistors of the first and second group pixels may not overlap the first driving circuit DC_L or the second driving circuit DC_R, and may be disposed in the first region AA1.

Referring to FIG. 4B and FIG. 4C, a width in the first direction DR1 occupied by six pixel driving units PDU, which are respectively connected to six light emitting units EPU, may be smaller than a width in the first direction DR1 occupied by the six light emitting units EPU. Since a portion of the driving circuit DC is disposed in the first region AA1, the pixel driving units PDU may be disposed in the second region AA2, so that a width in the first direction DR1 occupied by the light emitting device layer LDL may be greater than a width in the first direction DR1 occupied by the driving device layer DDL.

For example, a width WH in the first direction DR1 of a light emitting unit EPU may be greater than a width WH_C in the first direction DR1 of a pixel driving unit PDU corresponding thereto. For example, for convenience of description, a length WV in the second direction DR2 of the light emitting unit EPU and a length WV in the second direction DR2 of the pixel driving unit PDU are illustrated as being the same as each other, but embodiments are not limited thereto.

According to an embodiment, by designing the width WH_C of the pixel driving unit PDU to be smaller than the width WH of the light emitting unit EPU, it is possible to provide the display region DA having an area larger than the area occupied by the driving device layer DDL. Accordingly, the display panel 100 having a narrow bezel may be provided.

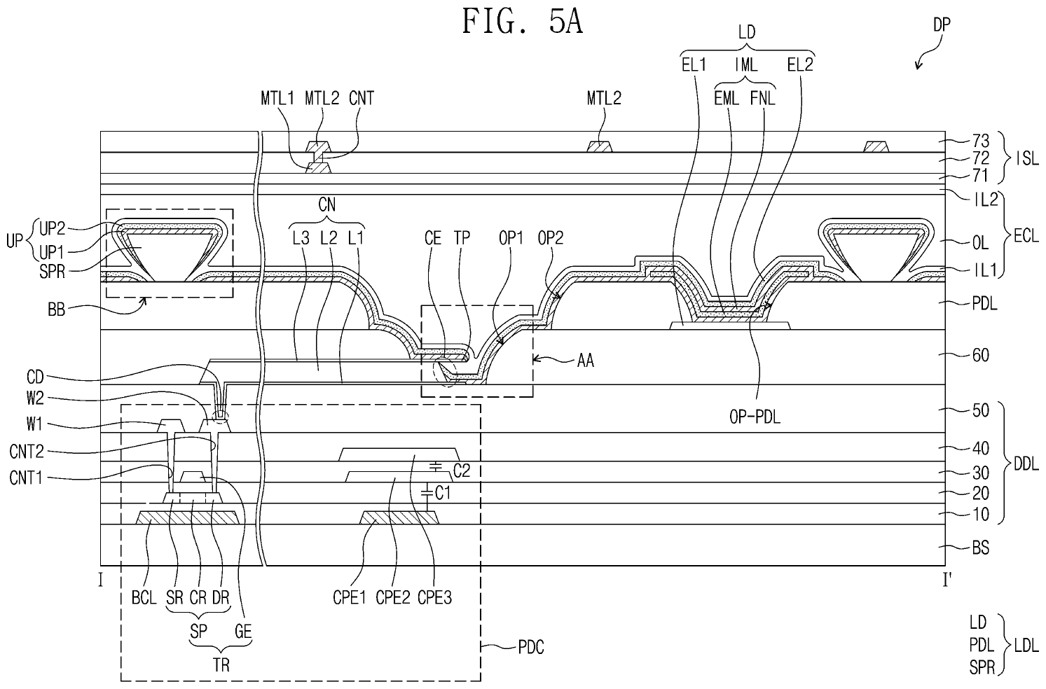

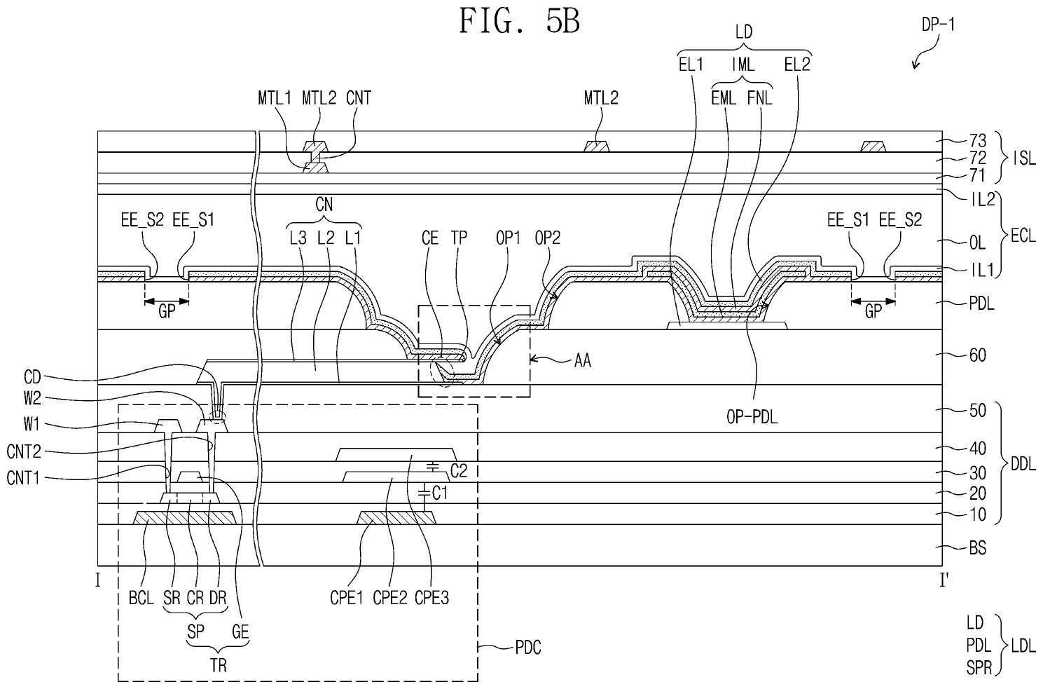

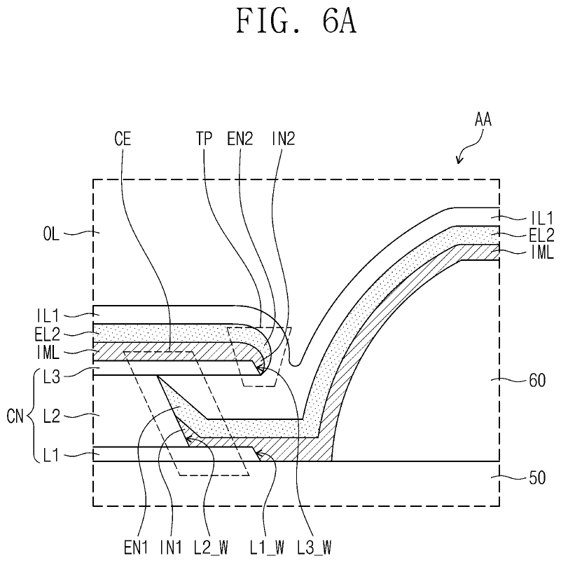

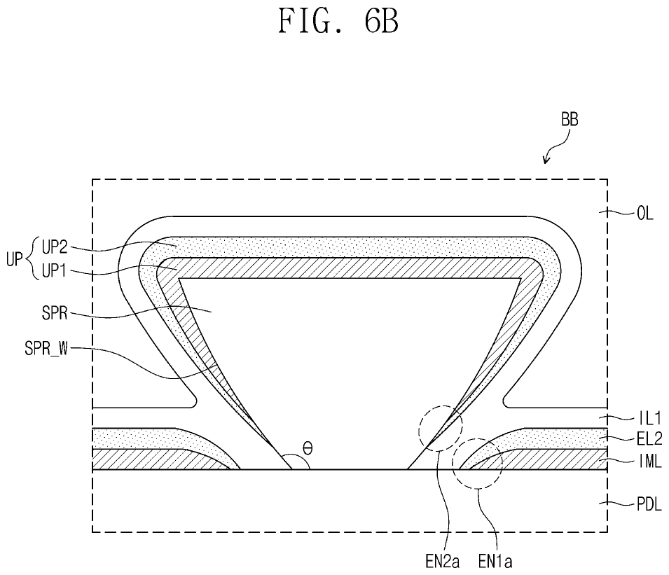

FIG. 5A and FIG. 5B are schematic cross-sectional views of display panels according to an embodiment. FIG. 6A is a schematic cross-sectional view of an enlarged partial region of a display panel according to an embodiment. FIG. 6B is a schematic cross-sectional view of a partial region of a display panel according to an embodiment. FIG. 5B illustrates a region corresponding to FIG. 5A, FIG. 6A illustrates a schematic cross-sectional view of an enlarged AA region of FIG. 5A, and FIG. 6B illustrates a schematic cross-sectional view of an enlarged BB region of FIG. 5A. Hereinafter, with reference to FIG. 5A to FIG. 6B, an embodiment will be described.

The display panel 100 may include a base layer BS, a driving device layer DDL disposed on the base layer BS, and a light emitting device layer LDL disposed on the driving device layer DDL.

Referring to FIG. 5A, the display panel DP according to an embodiment may include a base layer BS, a driving device layer DDL, a light emitting device layer LDL, an encapsulation layer ECL, and a sensing layer ISL. The driving device layer DDL may include insulation layers 10, 20, 30, 40, and 50 disposed on the base layer BS, and conductive pattern layers and semiconductor pattern layers disposed between the insulation layers. The conductive pattern layers and the semiconductor pattern layers may be disposed between the insulation layers and form a pixel driver PDC. In FIG. 5A, for convenience of description, a cross-section of one region of among regions in which one emitting part is disposed.

The base layer BS may be a member which provides a base surface on which the pixel driver PDC is disposed. The base layer BS may be a rigid substrate, or a flexible substrate that is bendable, foldable, rollable, and the like. The base layer BS may be a glass substrate, a metal substrate, a polymer substrate, or the like. However, embodiments are not limited thereto, and the base layer BS may be an inorganic layer, an organic layer, or a composite material layer.

The base layer BS may have a multi-layered structure. The base layer BS may include a first polymer resin layer, a silicon oxidelayer (SiOₓ) disposed on the first polymer resin layer, an amorphous siliconlayer (a-Si) disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. For example, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. For example, in the description, “˜˜-based” resin means that a functional group of “˜˜” is included.

Each of insulation layers, conductive layers, and semiconductor layers disposed on the base layer BS may be formed by a coating process, a deposition process, or the like. Thereafter, an insulation layer, a semiconductor layer, and a conductive layer may be selectively patterned by performing a photolithography process a plurality of times to form a hole in the insulation layer, or to form a semiconductor pattern layer, a conductive pattern layer, a signal line, and the like.

The driving device layer DDL may include first to fifth insulation layers 10, 20, 30, 40, and 50 and the pixel driver PDC sequentially laminated on the base layer BS. FIG. 5A illustrates one transistor TR and two capacitors CI and C2 in the pixel driver PDC. The transistor TR may correspond to a transistor connected to the light emitting device LD through a connection wiring CN, e.g., a connection transistor connected to a node (e.g., the fourth node N4 of FIG. 2A or the second node N2 of FIG. 2B) corresponding to the cathode of the light emitting device LD, and may correspond to the sixth transistor T6 of FIG. 2A or the first transistor Ti of FIG. 2B. For example, other transistors forming the pixel driver PDC may have a structure, which is the same as the structure of the transistor TR (hereinafter, a connection transistor) illustrated in FIG. 5A. However, this is an example, and the other transistors forming the pixel driver PDC may have a structure different from the structure of the transistor TR, and are not limited to any one embodiment.

On the base layer BS, the first insulation layer 10 may be disposed. The first insulation layer 10 may be an inorganic layer and/or an organic layer, and may have a single-layered structure or a multi-layered structure. The first insulation layer 10 may include at least one of an aluminum oxide, a titanium oxide, a silicon oxide, a silicon nitride, a silicon oxynitride, a zirconium oxide, or a hafnium oxide. In an embodiment, the first insulation layer 10 may be a single-layered silicon oxide layer. For example, insulation layers to be described below may be inorganic layers and/or organic layers, and may have a single-layered structure or a multi-layered structure. The inorganic layer may include at least one of the above-described materials, but embodiments are not limited thereto.

For example, the first insulation layer 10 may cover a bottom conductive layer BCL. For example, the display panel may further include the bottom conductive layer BC overlapping the connection transistor TR. The bottom conductive layer BCL may block an electric potential due to polarization of the base layer BS from affecting the connection transistor TR. For example, the bottom conductive layer BCL may block light incident to the connection transistor TR from a lower portion. Between the bottom conductive layer BCL and the base layer BS, at least one of an inorganic barrier layer and a buffer layer may be further disposed.

The bottom conductive layer BCL may include a reflective metal. For example, the bottom conductive layer BCL may include titanium (Ti), molybdenum (Mo), an alloy containing molybdenum, aluminum (Al), an alloy containing aluminum, an aluminum nitride (AlN), tungsten (W), a tungsten nitride (WN), copper (Cu), or the like.

In an embodiment, the lower conductive layer BCL may be connected to a source of the transistor TR through a source electrode pattern layer W1. For example, the bottom conductive layer BCL may be synchronized with the source of the transistor TR. However, this is an example, and the bottom conductive layer BCL may be connected to a gate of the transistor TR, thereby being synchronized with the gate of the transistor TR. In another example, the bottom conductive layer BCL may be connected to another electrode and be independently applied with a constant voltage or a pulse signal. The bottom conductive layer BCL may be provided in an isolated form from another conductive pattern layer. The bottom conductive layer BCL according to an embodiment may be provided in various forms, and is not limited to any one embodiment.

On the first insulation layer 10, the connection transistor TR may be disposed. The connection transistor TR may include a semiconductor pattern layer SP and a gate electrode GE. The semiconductor pattern layer SP may be disposed on the first insulation layer 10. The semiconductor pattern layer SP may include an oxide semiconductor. For example, the oxide semiconductor may include a transparent conductive oxide (TCO) such as an indium tin oxide (ITO), an indium zinc oxide (IZO), an indium gallium zinc oxide (IGZO), a zinc oxide (ZnO), an indium oxide (In₂O₃), or the like. However, embodiments are not limited thereto, and the semiconductor pattern layer may include amorphous silicon, low-temperature polycrystalline silicon, or polycrystalline silicon.

The semiconductor pattern layer SP may include a source region SR, a drain region DR, and a channel region CR which are divided according to the degree of conductivity. The channel region CR may be a portion overlapping the gate electrode GE in a plan view. The source region SR and the drain region DR may be portions spaced apart from each other by the channel region CR interposed therebetween. In case that the semiconductor pattern layer SP is an oxide semiconductor, the source region SR and the drain region DR may each be a reduced region. Accordingly, the source region SR and the drain region DR may have a relatively high reduced metal content ratio as compared to that of the channel region CR. In another example, in case that the semiconductor pattern layer SP is polycrystalline silicon, the source region SR and the drain region DR may each be a region doped to a high concentration.

The source region SR and the drain region DR may have relatively high conductivity as compared to that of the channel region CR. The source region SR may correspond to a source electrode of the connection transistor TR, and the drain region DR may correspond to a drain electrode of the connection transistor TR. As illustrated in FIG. 5A, a separate source electrode pattern layer W1 and a separate drain electrode pattern layer W2 respectively connected to the source region SR and the drain region DR may be further provided. For example, the separate source electrode pattern layer W1 and the separate drain electrode pattern layer W2 may each be formed as a single body with one of lines forming a pixel driver (see FIG. 2A and FIG. 2B), and are not limited to any one embodiment.

The second insulation layer 20 may commonly overlap pixels, and may cover the semiconductor pattern layer SP. The second insulation layer 20 may be an inorganic layer and/or an organic layer, and may have a single-layered structure or a multi-layered structure. The second insulation layer 20 may include at least one of an aluminum oxide, a titanium oxide, a silicon oxide, a silicon nitride, a silicon oxynitride, a zirconium oxide, or a hafnium oxide. In an embodiment, the second insulation layer 20 may be a single-layered silicon oxide layer.

The gate electrode GE may be disposed on the second insulation layer 20. The gate electrode GE may correspond to the gate of the connection transistor TR. For example, the gate electrode GE may be disposed on an upper side of the semiconductor pattern layer SP. However, this is an example, and the gate electrode GE may be disposed on a lower side of the semiconductor pattern layer DP, and is not limited to any one embodiment.

The gate electrode GE may include titanium (Ti), silver (Ag), molybdenum (Mo), aluminum (Al), an aluminum nitride, tungsten (W), a tungsten nitride (WN), copper (Cu), an alloy thereof, or the like, but embodiments are not limited thereto.

On the gate electrode GE, the third insulation layer 30 may be disposed. The third insulation layer 30 may be an inorganic layer and/or an organic layer, and may have a single-layered structure or a multi-layered structure. The fourth insulation layer 40 may include at least one of an aluminum oxide, a titanium oxide, a silicon oxide, a silicon nitride, a silicon oxynitride, a zirconium oxide, or a hafnium oxide.

A first capacitor electrode CPE1 and a second capacitor electrode CPE2 among conductive pattern layers W1, W2, CPE1, CPE2, and CPE3 may form a first capacitor C1. The first capacitor electrode CPE1 and the second capacitor electrode CPE2 may be spaced apart from each other by the first insulation layer 10 and the second insulation layer 20 interposed therebetween.

In an embodiment, the first capacitor electrode CPE1 and the lower conductive layer BCL may have a shape of a single body. For example, the second capacitor electrode CPE2 and the gate electrode GE may have a shape of a single body.

On the third insulation layer 30, a third capacitor electrode CPE3 may be disposed. The third capacitor electrode CPE3 may be spaced apart from the second capacitor electrode CPE2 by the third insulation layer 20 interposed therebetween, and may overlap the same. The third capacitor electrode CPE3 may form the second capacitor electrode CPE2 and a second capacitor C2.

On the third insulation layer 30 and/or the third capacitor electrode CPE3, the fourth insulation layer 40 may be disposed. The fourth insulation layer 40 may be an inorganic layer and/or an organic layer, and may have a single-layered structure or a multi-layered structure. The fourth insulation layer 40 may include at least one of an aluminum oxide, a titanium oxide, a silicon oxide, a silicon nitride, a silicon oxynitride, a zirconium oxide, or a hafnium oxide.

On the fourth insulation layer 40, the source electrode pattern layer W1 and the drain electrode pattern layer W2 may be disposed. The source electrode pattern layer W1 may be connected to a source region SR of the connection transistor TR through a first contact-hole CNT1, and the source electrode pattern layer W1 and the source region SR of the semiconductor pattern layer SP may function as a source of the connection transistor TR. The drain electrode pattern layer W2 may be connected to a drain region DR of the connection transistor TR through a second contact-hole CNT2, and the drain electrode pattern layer W2 and the drain region DR of the semiconductor pattern layer SP may function as a drain of the connection transistor TR. On the source electrode pattern layer W1 and the drain electrode pattern layer W2, the fifth insulation layer 50 may be disposed.

On the fifth insulation layer 50, the connection wiring CN may be disposed. The connection wiring CN may electrically connect the pixel driver PDC and the light emitting device LD. For example, the connection wiring CN may electrically connect the connection transistor TR and the light emitting device LD. The connection wiring CN may be a connection node for connecting the pixel driver PDC and the light emitting device LD. For example, the connection wiring CN may correspond to the fourth node N4 (see FIG. 2A) illustrated in FIG. 2A, or may correspond to the second node N2 (see FIG. 2B) illustrated in FIG. 2B. For example, this is an example, and as long as the connection wiring CN is connected to the light emitting device LD, the connection wiring CN may be defined as a connection node with various elements among elements forming the pixel driver PDC according to a design of the pixel driver PDC, and is not limited to any one embodiment.

On the connection wiring CN, the sixth insulation layer 60 may be disposed. The sixth insulation layer 60 may be disposed on the fifth insulation layer 50 and cover the connection wiring CN. The fifth insulation layer 50 and the sixth insulation layer 60 may each be an organic layer. For example, the fifth insulation layer 50 and the sixth insulation layer 60 may each include a general purpose polymer such as benzocyclobutene (BCB), polyimide, hexamethyldisiloxane (HMDSO), polymethylmethacrylate (PMMA) and polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, a blend thereof, or the like.

The sixth insulation layer 60 may include an opening which exposes at least a portion of the connection wiring CN. The connection wiring CN may be electrically connected to the light emitting device LD through the portion exposed from the sixth insulation layer 60. For example, the connection wiring CN may electrically connect the connection transistor TR and the light emitting device LD. A detailed description thereof will be described below. For example, in the display panel DP according to an embodiment, the sixth insulation layer 60 may be omitted, or be provided in plurality, and is not limited to any one embodiment.

On the sixth insulation layer 60, the light emitting device layer LDL may be disposed. The light emitting device layer LDL may include a pixel definition film PDL, a light emitting device LD, and a separator SPR. The pixel definition film PDL may be an organic layer. For example, the pixel definition film PDL may include a general purpose polymer such as benzocyclobutene (BCB), polyimide, hexamethyldisiloxane (HMDSO), polymethylmethacrylate (PMMA) and polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, a blend thereof, or the like.

In an embodiment, the pixel definition film PDL may have properties of absorbing light, and for example, may have a black color. For example, the pixel definition film PDL may include a black coloring agent. The black coloring agent may include a black dye and a black pigment. The black coloring agent may include carbon black, or a metal such as chromium or an oxide thereof. The pixel definition film PDL may correspond to a light blocking pattern layer having light blocking properties.

On the pixel definition film PDL, an opening OP-PDL (hereinafter, a light emitting opening) which exposes at least a portion of a first electrode EL1 to be described below may be defined. The light emitting opening OP-PDL may be provided in plurality and be disposed corresponding to each light emitting device. The light emitting opening OP-PDL may have all constituent elements of the light emitting device LD disposed therein overlapping each other, and may be substantially a region in which light emitted by the light emitting device LD is displayed. Accordingly, the shape of the above-described emitting part EP (see FIG. 2) may substantially correspond to the shape of the light emitting opening OP-PDL in a plan view.

The light emitting device LD may include the first electrode EL1, an intermediate layer IML, and a second electrode EL2. The first electrode EL1 may be a transflective electrode, a transmissive electrode, or a reflective electrode. According to an embodiment, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), a compound thereof, or the like, and a transparent or translucent electrode layer formed on the reflective layer. The transparent or translucent electrode layer may be provided with at least one selected from the group consisting of an indium tin oxide (ITO), an indium zinc oxide (IZO), an indium gallium zinc oxide (IGZO), a zinc oxide (ZnO), or an indium oxide (In₂O₃), and an aluminum-doped zinc oxide (AZO). For example, the first electrode EL1 may include a laminated structure of ITO/Ag/ITO.

In an embodiment, the first electrode EL1 may be the anode of the light emitting device LD. For example, the first electrode EL1 may be connected to the first power line VDL (see FIG. 2A) and may be applied with the first power voltage VDD (see FIG. 2A). The first electrode EL1 may be connected to the first power line VDL in the display region DA, or may be connected to the first power line VDL in the peripheral region NDA. For example, the first power line VDL may be disposed in the peripheral region NDA, and the first electrode EL1 may have a shape extending to the peripheral region NDA.

In the cross-sectional view of FIG. 5A, the first electrode EL1 is illustrated as overlapping the light emitting opening OP-PDL and not overlapping the separator SPR, but as described above with reference to FIG. 4C, the first electrode EL1 of each light emitting device may have a shape of a single body, and may have a mesh shape or a lattice shape in which openings are defined in some regions. For example, as long as the same first power voltage VDD is applied to the first electrode EL1 of each of the light emitting devices, the shape of the first electrode EL1 may be provided in various ways, and is not limited to any one embodiment.

The intermediate layer IML may be disposed between the first electrode EL1 and the second electrode EL2. The intermediate layer IML may include an emitting layer EML and a functional layer FNL. The light emitting device LD may include the intermediate layer IML of various structures, and is not limited to any one embodiment. For example, the functional layer FNL may be provided as layers, or may be provided as two or more layers spaced apart from each other by the emitting layer EML interposed therebetween. In another example, in an embodiment, the functional layer FNL may be omitted.

The emitting layer EML may include an organic light emitting material. For example, the emitting layer EML may include an inorganic light emitting material, or may be provided as a mixed layer of an organic light emitting material and an inorganic light emitting material. In an embodiment, the emitting layers EML included in adjacent emitting parts EP may each include a light emitting material displaying a different color from each other. For example, the emitting layer EML included in each emitting part EP may provide light of any one of blue, red, and/or green colors. However, embodiments are not limited thereto, and the emitting layers EML disposed in all emitting parts EP may each include a light emitting material displaying the same color. For example, the emitting layer EML may provide blue light, or may provide white light. For example, although an embodiment in which the emitting layer EML and the functional layer FNL have different shapes is illustrated in FIG. 5A, embodiments are not limited thereto, and the emitting layer EML and the functional layer FNL may be disposed in the same shape in a plan view.

The functional layer FNL may be disposed between the first electrode EL1 and the second electrode EL2. For example, the functional layer FNL may be disposed between the first electrode EL1 and the emitting layer EML, or be disposed between the second electrode EL2 and the emitting layer EML. In another example, the functional layer FNL may be disposed both between the first electrode EL1 and the emitting layer EML and between the second electrode EL2 and the emitting layer EML. In an embodiment, the emitting layer EML may be inserted into the functional layer FNL. However, this is an example, and the functional layer FNL may include a layer disposed between the emitting layer EML and the first electrode EL1, and/or a layer disposed between the emitting layer EML and the second electrode EL2, and may be provided in plurality, but is not limited to any one embodiment.

The functional layer FNL may control the movement of charges between the first electrode EL1 and the second electrode EL2. The functional layer FNL may include a hole injection/transport material and/or an electron injection/transport material. The functional layer FNL may include at least one of an electron blocking layer, a hole transport layer, a hole injection layer, a hole blocking layer, an electron transport layer, an electron injection layer, and a charge generation layer.

The second electrode EL2 may be disposed on the intermediate layer IML. As described above, the second electrode EL2 may be connected to the connection wiring CN and be electrically connected to the pixel driver PDC. For example, the second electrode EL2 may be electrically connected to the connection transistor TR through the connection wiring CN.

As described above, the connection wiring CN may include a driver connection part CD and an emission connection part CE. The driver connection part CD may be a portion of the connection wiring CN that is connected to the pixel driver PDC, and may be a portion substantially connected to the connection transistor TR. In an embodiment, the driver connection part CD may pass through the fifth insulation layer 50 and be electrically connected to the drain region DR of the semiconductor pattern layer SP through the drain electrode pattern layer W2. The emission connection part CE may be a portion of the connection wiring CN that is connected to the light emitting device LD. The emission connection part CE may be defined in a region exposed from the sixth insulation layer 60, and may be a portion to which the second electrode EL2 is connected. For example, a tip part TP may be defined in the emission connection part CE.

For example, a transistor connected to the driver connection part CD of the connection wiring CN may be variously changed according to the configuration of the pixel circuits PDC and PDC-1. For example, in case that the display panel 100 according to an embodiment is designed as the pixel driver PDC illustrated in FIG. 2A, the transistor TR connected to the driver connection part CD of the connection wiring CN may be the sixth transistor T6 (see FIG. 2A). In case that the connection wiring CN is used for an electrical connection between the second electrode EL2 of the emitting part EP and a pixel circuit, the connection wiring CN may be connected to various transistors forming the pixel circuit, and is not limited to any one embodiment.

The emission connection part CE of the connection wiring CN will be described in more detail with reference to FIG. 5A and FIG. 6A. The connection wiring CN may have a three-layered structure. For example, the connection wiring CN may include a first layer L1, a second layer L2, and a third layer L3 which are sequentially laminated along a third direction DR3. The second layer L2 may include a material different from that of the first layer L1. For example, the second layer L2 may include a material different from that of the third layer L3. The second layer L2 may be relatively thicker than the first layer L1. For example, the second layer L2 may be relatively thicker than the third layer L3. The second layer L2 may include a highly conductive material. In an embodiment, the second layer L2 may include aluminum (Al).

For example, the first layer L1 may include a material having a lower etch rate than the second layer L2. For example, the first layer L1 and the second layer L2 may be composed of materials having a high etch selection ratio to each other. In an embodiment, the first layer L1 may include titanium (Ti), and the second layer L2 may include aluminum (Al). For example, a side surface L1_W of the first layer L1 may be protruded further outside than a side surface L2_W of the second layer L2. For example, the emission connection part CE of the connection wiring CN may have a shape in which the side surface L1_W of the first layer L1 protrudes outward from the side surface L2_W of the second layer L2. For example, the emission connection part CE of the connection wiring CN may have a shape in which the side surface L2_W of the second layer L2 is recessed inward from the side surface L1_W of the first layer L1.

For example, the third layer L3 may include a material having a lower etch rate than the second layer L2. For example, the third layer L3 and the second layer L2 may be composed of materials having a high etch selection ratio to each other. In an embodiment, the third layer L3 may include titanium (Ti), and the second layer L2 may include aluminum (Al). For example, a side surface L3_W of the third layer L3 may be protruded further outside than the side surface L2_W of the second layer L2. For example, the emission connection part CE of the connection wiring CN may have a shape in which the side surface L3_W of the third layer L3 protrudes outward from the side surface L2_W of the second layer L2. For example, the emission connection part CE of the connection wiring CN may have an undercut shape or an overhang structure, and the tip part TP of the emission connection part CE may be defined by a portion in the third layer L3 that further protrudes than the second layer L2.

The sixth insulation layer 60 and the pixel definition film PDL may expose at least a portion of the tip part TP and at least a portion of the side surface L2_W. For example, a first opening OP1 exposing a side of the connection wiring CN may be defined on the sixth insulation layer 60, and a second opening OP2 overlapping the first opening OP1 may be defined on the pixel definition film PDL. A planar area of the second opening OP2 may be greater than that of the first opening OP1. However, embodiments are not limited thereto, and as long as at least a portion of the tip part TP and at least a portion of the side surface L2_W are exposed, the planar area of the second opening OP2 may be less than or equal to that of the first opening OP1.

On the pixel definition film PDL, the intermediate layer IML may be disposed. The intermediate layer IML may be disposed on some regions of the sixth insulation layer 60 exposed by the second opening OP2 of the pixel definition film PDL. For example, the intermediate layer IML may be disposed on some regions of the connection wiring CN exposed by the first opening OP1 of the sixth insulation 60. As illustrated in FIG. 6A, the intermediate layer IML may include an end portion IN1 disposed along an upper surface of the fifth insulation layer 50 and another end portion IN2 disposed along an upper surface of the tip part TP. For example, when viewed on a cross-section, the intermediate layer IML may have a shape in which the connection is partially disconnected with respect to the tip part TP in a region in which the emission connection part CE is defined. However, in a plan view, the intermediate layer IML may have a shape of a single body entirely connected within a region (see FIG. 4) defined as a closed line by a separator.

On the intermediate layer IML, the second electrode EL2 may be disposed. The second electrode EL2 may be disposed on some regions of the sixth insulation layer 60 exposed by the second opening OP2 of the pixel definition film PDL. For example, the second electrode EL2 may also be disposed on some regions of the connection wiring CN exposed by the first opening OP1 of the sixth insulation 60. As illustrated in FIG. 6A, the second electrode EL2 may include an end portion EN1 of the second electrode EL2 disposed along the upper surface of the fifth insulation layer 50 and another end portion EN2 disposed along of the upper surface of the tip part TP. For example, when viewed on a cross-section, the second electrode EL2 may have a shape in which the connection is partially disconnected with respect to the tip part TP in a region in which the emission connection part CE is defined. However, in a plan view, the second electrode EL2 may have a shape of a single body entirely connected within a region (see FIG. 4) defined as a closed line by a separator.

For example, an end portion EN1 of the second electrode EL2 may be disposed along a side surface of the second layer L2 and be in contact with the side surface L2_W of the second layer L2. For example, through a difference between deposition angles of the second electrode EL2 and the intermediate layer IML, the second electrode EL2 may be formed to be in contact with the side surface L2_W of the second layer L2 exposed from the intermediate layer IML by the tip part TP. For example, the second electrode EL2 may be connected to the connection wiring CN without a separate patterning process for the intermediate layer IML, and accordingly, the light emitting device LD may be electrically connected to the pixel driver PDC through the connection wiring CN.

In an embodiment, the other end portion IN2 of the intermediate layer IML and another end portion EN2 of the second electrode EL2 may cover the side surface L3_W of the third layer L3, but this is an example, and at least a portion of the side surface L3_W of the third layer L3 may be exposed from the other end portion IN2 of the intermediate layer IML and/or another end portion EN2 of the second electrode EL2.

Referring to FIG. 5A and FIG. 6B, the separator SPR will be described in more detail. As illustrated in FIG. 6B, the separator SPR may have a reverse tapered shape. For example, an angle θ (hereinafter, a taper angle) formed by a side surface SPR_W of the separator SPR with respect to the upper surface of the pixel definition film PDL may be an obtuse angle. However, this is an example, and as long as the separator SPR electrically disconnects the second electrode EL2 for each pixel, the taper angle θ may be set in various ways. For example, the separator SPR may have the same structure as that of the tip part TP, and is not limited to any one embodiment.

In an embodiment, the separator SPR may include a material having insulation properties, and may include an organic insulation material. The separator SPR may include an inorganic insulation material, and may be formed in multiple layers of an organic insulation material and an inorganic insulation material, and may include a conductive material according to an embodiment. For example, as long as the second electrode EL2 is electrically disconnected for each pixel, the type of material of the separator SPR is not limited.

In an upper portion of the separator SPR, a dummy layer UP may be disposed. The dummy layer UP may include a first dummy layer UP1 disposed on the separator SPR and a second dummy layer UP2 disposed on the first dummy layer UP1. The first dummy layer UP1 and the intermediate layer IMP may be formed by the same process and may include the same material. The second dummy layer UP2 and the second electrode EL2 may be formed by the same process and may include the same material. For example, the first dummy layer UP1 and the second dummy layer UP2 may be simultaneously formed in case that the intermediate layer IML and the second electrode EL2 are formed. In another example, the display panel DP may not include the dummy layer UP.

As illustrated in FIG. 6B, in an embodiment, the second electrode EL2 may include a first end portion EN1a, and the second dummy layer UP2 may include a second end portion EN2a. The first end portion EN1a may be spaced apart from the separator SPR and be positioned on the pixel definition film PDL, and the second end portion EN2a may be separated from the first end portion EN1a and positioned on a side surface SPR_W of the separator SPR. However, in FIG. 6B, the first end portion EN1a is illustrated as being spaced apart at a predetermined interval from the side surface SPR_W of the separator SPR, but embodiments are not limited thereto. For example, in case that the first end portion EN1a is electrically disconnected from the second end portion EN2a, the first end portion EN1a may also contact the side surface SPR_W of the separator SPR. For example, although the first end portion EN1a and the second end portion EN2a are connected without being distinguished from each other, in case that a portion formed along the side surface SPR_W of the separator SPR is thin so that electrical resistance is high and the second electrode EL2 is electrically disconnected between adjacent pixels, it may be considered that the second electrode EL2 is partitioned by the separator SPR.

According to an embodiment, although there is no separate patterning process for the second electrode EL2 or the intermediate layer IML, by preventing the second electrode EL2 or the intermediate layer IML from being formed on the side surface SPR_W of the separator SPR or by forming the same thin, the second electrode EL2 or the intermediate layer IML may be partitioned for each pixel. For example, as long as the second electrode EL2 or the intermediate layer IML is electrically disconnected between adjacent pixels, the shape of the separator SPR may be changed in various ways, and is not limited to any one embodiment.

In another example, as illustrated in FIG. 5B, the separator SPR may be omitted in the display panel DP. For example, the second electrode EL2 and the intermediate layer IML may be separated from an adjacent light emitting device through a patterning process and be independently provided for each light emitting device. The second electrode EL2 and the intermediate layer IML may include edges EE_S1 and EE_S2 spaced apart from each other with a gap GP interposed therebetween in a plan view, and the edges EE_S1 and EE_S2 may respectively form different emitting parts from each other. Therefore, each emitting part may have an independent second electrode EL2 with the gap GP interposed therebetween.

Referring back to FIG. 5A and FIG. 5B, the encapsulation layer ECL may be disposed on the light emitting device layer LDL. The encapsulation layer ECL may cover the light emitting device LD and may cover the separator SPR. The encapsulation layer ECL may include a first inorganic layer Ill, an organic layer OL, and a second inorganic layer IL2 which are sequentially laminated. However, embodiments are not limited thereto, and the encapsulation layer ECL may further include inorganic layers and organic layers. For example, the encapsulation layer ECL may be a glass substrate.

The first and second inorganic layers IL1 and IL2 may protect the light emitting device LD from external moisture and oxygen, and the organic layer OL may protect the light emitting device LD from foreign materials such as particles remaining in a process of forming the first inorganic layer ILL The first and second inorganic layers IL1 and IL2 may include a silicon nitride layer, a silicon oxynitride layer, a silicon oxide layer, a titanium oxide layer, an aluminum oxide layer, or the like. The organic layer OL may include an acrylic organic layer, and the type of material of the organic layer OL is not limited to any one embodiment.

The sensing layer ISL may sense an external input. In an embodiment, the sensing layer ISL may be formed on the encapsulation layer ECL through a continuous process. For example, the sensing layer ISL may be disposed (e.g., directly disposed) on the encapsulation layer ECL. Being directly disposed may mean that there is no component disposed between the sensing layer ISL and the encapsulation layer ECL. For example, a separate adhesive member may not be disposed between the sensing layer ISL and the encapsulation layer ECL. However, this is an example, and in the display panel DP according to an embodiment, the sensing layer ISL may be separately formed and coupled to the display panel DP by an adhesive member, and is not limited to any one embodiment.

The sensing layer ISL may include conductive layers and insulation layers. The conductive layers may include a first sensing conductive layer MTL1 and a second sensing conductive layer MTL2, and the insulation layers may include first to third sensing insulation layers 71, 72, and 73. However, this is an example, and the number of conductive layers and the number of insulation layers are not limited to any one embodiment.

Each of the first to third sensing insulation layers 71, 72, and 73 may have a single-layered structure, or may have a multi-layered structure in which layers are laminated along the third direction DR3. The first to third sensing insulation layers 71, 72, and 73 may include an inorganic film. The inorganic film may include at least one of an aluminum oxide, a titanium oxide, a silicon oxide, a silicon nitride, a silicon oxynitride, a zirconium oxide, or a hafnium oxide. The first to third sensing insulation layers 71, 72, and 73 may include an organic film. The organic film may include at least one of an acrylic resin, a methacrylic resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The first sensing conductive layer MTL1 may be disposed between the first sensing insulation layer 71 and the second sensing insulation layer 72, and the second sensing conductive layer MTL2 may be disposed between the second sensing insulation layer 72 and the third sensing insulation layer 73. A portion of the second sensing conductive layer MTL2 may be connected to the first sensing conductive layer MTL1 through a contact-hole CNT formed on the second sensing insulation layer 72. Each of the first sensing conductive layer MTL1 and the second sensing conductive layer MTL2 may have a single-layered structure, or may have a multi-layered structure in which layers are laminated along the third direction DR3.

A sensing conductive layer of a single-layered structure may include a metal layer or a transparent conductive layer. The metal layer may include molybdenum, silver, titanium, copper, aluminum, or an alloy thereof. The transparent conductive layer may include a transparent conductive oxide such as an indium tin oxide (ITO), an indium zinc oxide (IZO), a zinc oxide (ZnO), an indium zinc tin oxide (IZTO), or the like. In another example, the transparent conductive layer may include a conductive polymer such as PEDOT, a metal nanowire, graphene, and the like.

A sensing conductive layer of a multi-layered structure may include metal layers. The metal layers may have, for example, a three-layered structure of titanium(Ti)/aluminum(Al)/titanium (Ti). In another example, a conductive layer of a multi-layered structure may include at least one metal layer and at least one transparent conductive layer.

The first sensing conductive layer MTL1 and the second sensing conductive layer MTL2 may form a sensor that senses an external input in the sensing layer ISL. The sensor may be driven by a capacitive method and may be driven in either a mutual-cap capacitive method or a self-cap capacitive method. However, this is an example, and the sensor may be driven by a resistive film method, an ultrasonic method, or an infrared method in addition to the capacitive method, and is not limited to any one embodiment.

Each of the first sensing conductive layer MTL1 and the second sensing conductive layer MTL2 may include a transparent conductive oxide, or may have a metal mesh shape formed of an opaque conductive material. The first sensing conductive layer MTL1 and the second sensing conductive layer MTL2 may have various materials and various shapes as long as the visibility of an image displayed by the display panel DP is not degraded, and are not limited to any one embodiment.

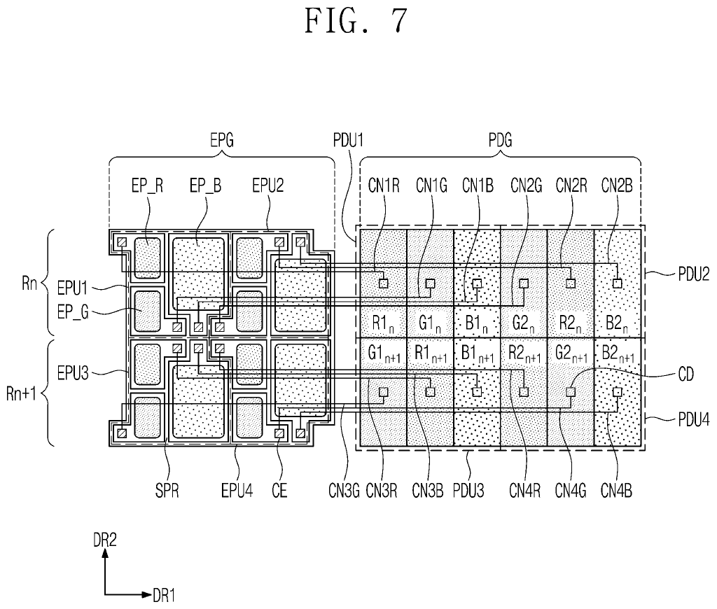

FIG. 7 is a drawing illustrating a display panel according to an embodiment. Hereinafter, an embodiment will be described with reference to FIG. 7. For example, the same reference numerals are given to the same components as those described with reference to FIG. 1 to FIG. 6B, and redundant descriptions thereof will be omitted for descriptive convenience.

In FIG. 7, a light emitting group EPG including two rows Rn and Rn+1 (hereinafter, a first row, and a second row) and a pixel driving group PDG connected thereto are schematically illustrated. For example, for convenience of description, some components are omitted.

As illustrated in FIG. 7, the light emitting group EPG may include a first light emitting unit EPU1 and a second light emitting unit EPU2 forming the first row Rn, and a third light emitting unit EPU3 and a fourth light emitting unit EPU4 forming the second row Rn+1. Each of the first to fourth light emitting units EPU1 to EPU4 may include first to third emitting parts EP_R, EP_G, and EP_B, and is illustrated with different shades for distinction. As illustrated, each of the emitting parts EP_R, EP_G, and EP_B may include a second electrode EL2 divided by a separator SPR.

Each of the first to fourth light emitting units EPU1 to EPU4 may include emitting parts that do not overlap the pixel driving group PDG in a plan view. For example, the first to fourth light emitting units EPU1 to EPU4 may be included in the first group G2L (see FIG. 3A).

The pixel driving group PDG may include pixel circuits R1n, G1n, B1n, G2n, R2n, B2n, G1n+1, R1n+1, B1n+1, R2n+1, G2n+1, and B2n+1 connected to each of emitting parts forming the first to fourth light emitting units EPU1 to EPU4. For convenience of description, the pixel circuits R1n, G1n, B1n, G2n, R2n, B2n, G1n+1, R1n+1, B1n+1, R2n+1, G2n+1, and B2n+1 are illustrated with shades corresponding to emitting parts connected thereto, and are illustrated in quadrangular shapes.

Emitting parts of the light emitting group EPG may be connected to pixel circuits of the pixel driving group PDG through connection wirings CN1R, CN1G, CN1B, CN2G, CN2R, CN2B, CN3G, CN3R, CN3B, CN4R, CN4G, and CN4B, respectively. Each of the connection wirings CN1R, CN1G, CN1B, CN2G, CN2R, CN2B, CN3G, CN3R, CN3B, CN4R, CN4G, and CN4B may correspond to the connection wiring CN illustrated in FIG. 5A and FIG. 5B.

Among the connection wirings CN1R, CN1G, CN1B, CN2G, CN2R, CN2B, CN3G, CN3R, CN3B, CN4R, CN4G, and CN4B, first to sixth connection wirings CN1R, CN1G, CN1B, CN2R, CN2G, and CN2B may be disposed in the first row Rn and connect the emitting parts of the first and second light emitting units EPU1 and EDU2 to pixel circuits R1n, G1n, B1n, G2n, R2n, and B2n of the first row Rn. Among the connection wirings CN1R, CN1G, CN1B, CN2G, CN2R, CN2B, CN3G, CN3R, CN3B, CN4R, CN4G, and CN4B, seventh to twelfth connection wirings CN3R, CN3G, CN3B, CN4R, CN4G, and CN4B may be disposed in the second row Rn+1 and connect the emitting parts of the third and fourth light emitting units EPU3 and EPU4 to pixel circuits R1n+1, G1n+1, B1n+1, G2n+1, R2n+1, and B2n+1 of the second row Rn+1.

Each of the connection wirings CN1R, CN1G, CN1B, CN2R, CN2G, CN2B, CN3R, CN3G, CN3B, CN4R, CN4G, and CN4B may include an emission connection part CE and a driver connection part CD. The emission connection parts CE may be disposed on a side of each of the connection wirings CN1R, CN1G, CN1B, CN2R, CN2G, CN2B, CN3R, CN3G, CN3B, CN4R, CN4G, and CN4B and connected to each of the emitting parts EP_R, EP_G, and EP_B, and the driver connection parts CD may be disposed on another side of each of the connection wirings CN1R, CN1G, CN1B, CN2R, CN2G, CN2B, CN3R, CN3G, CN3B, CN4R, CN4G, and CN4B and connected to each of the pixel circuits R1n, G1n, B1n, G2n, R2n, B2n, G1n+1, R1n+1, B1n+1, R2n+1, G2n+1, and B2n+1.

As described above, the emission connection parts CE may be portions where the light emitting unit EP (see FIG. 5A), e.g., the second electrode EL2 (see FIG. 5A) and the connection wiring CN (see FIG. 5A), are connected. The emission connection parts CE may be provided at positions spaced apart from the emitting layer EML (see FIG. 5A), and overlapping the second electrode EL2. Accordingly, the emission connection parts CE may be disposed in the separator SPR, and are illustrated at positions spaced apart from dotted emitting parts.

Since the driver connection parts CD are portions where the connection wiring CN and the driving transistor T1 (see FIG. 5A) are connected, positions of the driver connection parts CD may substantially correspond to a position of the driving transistor T1. In an embodiment, the driver connection parts CD may be arranged along the first direction DR1. Driver connection parts CD of the first row Rn may be arranged along the first direction DR1, and driver connection parts CD of the second row Rn+1 may be also arranged along the first direction DR1.

According to an embodiment, the order (or arrangement order) in which the driver connection parts CD are arranged along the first direction DR1 may correspond to the order (or arrangement order) in which the emitting parts EP_R, EP_G, and EP_B are arranged along the first direction DR1, and may correspond to the order (or arrangement order) in which the emission connection parts CE are arranged along the first direction DR1.

For example, the order (or arrangement order) in which the emission connection parts CE are arranged along the first direction DR1 in the first row Rn may be the order (or arrangement order) of the first emitting part EP_R, the second emitting part EP_G, and the third emitting part EP_B of the first light emitting unit EPU1 and the second emitting part EP_G, the first emitting part EP_R, and the third emitting part EP_B of the second light emitting unit EPU2. Accordingly, the order (or arrangement order) in which the driver connection parts CD are arranged along the first direction DR1 in the first row Rn may be the order (or arrangement order) of a first pixel circuit R1n, a second pixel circuit Gln, a third pixel circuit B In of a first pixel driving unit PDU1 and a second pixel circuit G2n, a first pixel circuit R2n, and a third pixel circuit B2n of a second pixel driving unit PDU2.

The order (or arrangement order) in which the emission connection parts CE are arranged along the first direction DR1 in the second row Rn+1 may be the order (or arrangement order) of the second emitting part EP_G, the first emitting part EP_R, and the third emitting part EP_B of the third light emitting unit EPU3 and the first emitting part EP_R, the second emitting part EP_G, and the third emitting part EP_B of the fourth light emitting unit EPU4. Accordingly, the order (or arrangement order) in which the driver connection parts CD are arranged along the first direction DR1 in the second row Rn+1 may be the arrangement order of a second pixel circuit G1n+1, a first pixel circuit R1n+1, a third pixel circuit B1n+1 of a third pixel driving unit PDU3 and a first pixel circuit R2n+1, a second pixel circuit G2n+1, and a third pixel circuit B2n+1 of a fourth pixel driving unit PDU4.

According to an embodiment, the arrangement of emitting parts of the light emitting units EPU may be the same in the first row Rn and the second row Rn+1. For example, the arrangement of pixel circuits in the pixel driving units PDU1, PDU2, PDU3, and PDU4 may be different from each other in the first row Rn and the second row Rn+1. For example, the first pixel circuit R1n of the first row Rn may be a pixel circuit for driving the first emitting part EP_R which emits a red light, and the first pixel circuit G1n+1 of the second row Rn+1 may be a pixel circuit for driving the second emitting part EP_G which emits a green light.

In an embodiment, the driver connection parts CD may be disposed to be arranged along the first direction DR1. When viewed in the first direction DR1 according to the arrangement of each of the emitting parts EP_R, EP_G, and EP_B, the emission connection parts CE may be disposed on an upper side or a lower side than the driver connection parts CD.

For example, the connection wirings CN1R, CN1G, CN1B, CN2R, CN2G, CN2B, CN3R, CN3G, CN3B, CN4R, CN4G, and CN4B may be disposed in a region between the driver connection parts CD and the emission connection parts CE. For example, a first connection wiring CN1R connected to the first emitting part EP_R of the first light emitting unit EPU1, a fourth connection wiring CN2R connected to the first emitting part EP_R of the second light emitting unit EPU2, and a sixth connection wiring CN2B connected to the third emitting part EP_B of the second light emitting unit EPU2 may be disposed on an upper portion of the driver connection parts CD, and a second connection wiring CN1G connected to the second emitting part EP_G of the first light emitting unit EPU1, a third connection wiring CN2B connected to the third emitting part EP_B of the first light emitting unit EPU1, and a fifth connection wiring CN2G connected to the second emitting part EP_G of the second light emitting unit EPU2 may be disposed on a lower portion of the driver connection parts CD.

According to an embodiment, by designing the order (or arrangement order) in which the driver connection parts CD are arranged along the first direction DR1 to be the same as the order (or arrangement order) in which the emission connection parts CE are arranged along the first direction DR1, the order of pixel driving circuits may be the same as the order (or arrangement order) in which the emission connection parts CE are arranged along the first direction DR1. Accordingly, the density of connection wirings may be reduced, so that the degree of freedom in design of the connection wirings may be improved. Since a larger number of connection wirings may be disposed within the same area, although the non-overlapping degree to which the pixel driver PDC and the emitting part EP do not overlap, a stable connection may be achieved. Therefore, a display panel having a narrow bezel may be stably provided.

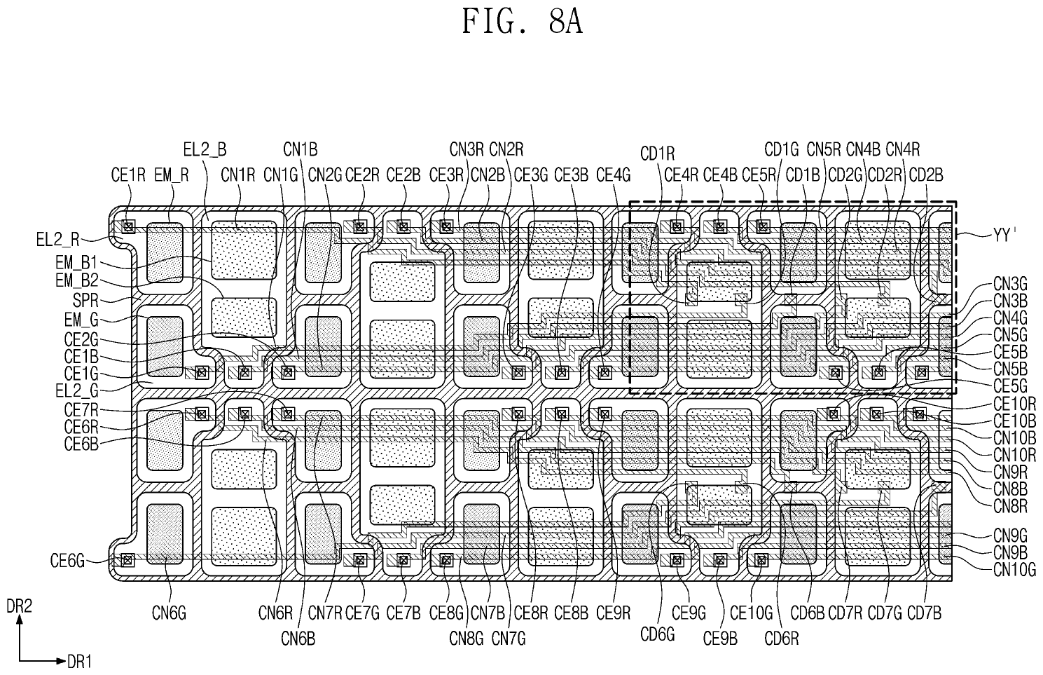

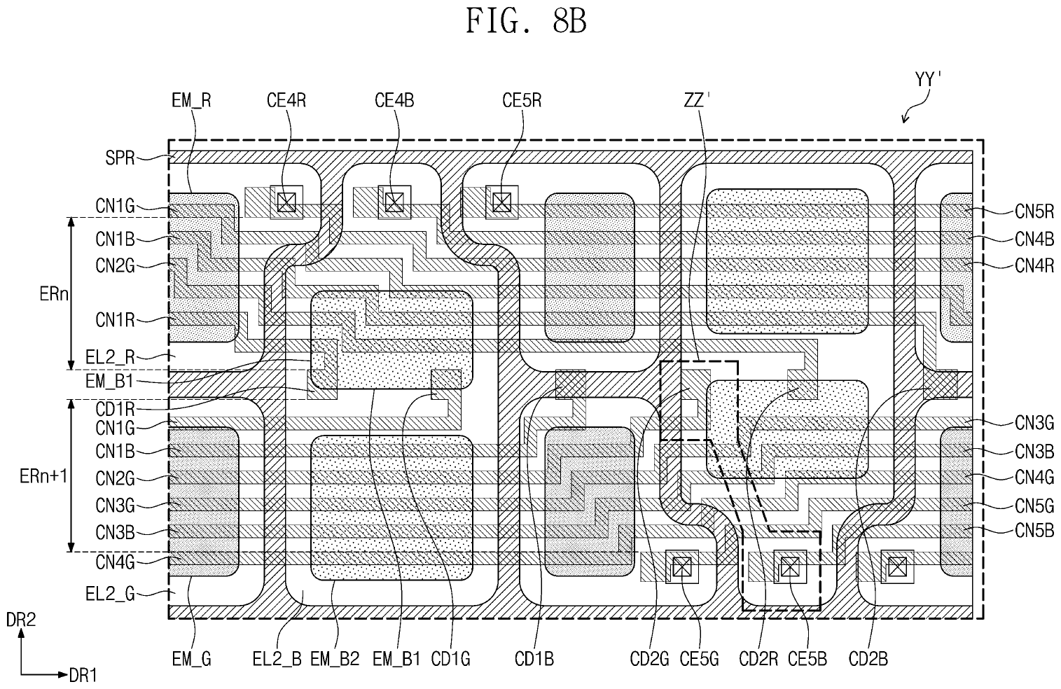

FIG. 8A is a schematic plan view illustrating a partial region of a display panel according to an embodiment. FIG. 8B is a schematic plan view illustrating an enlarged YY′ region illustrated in FIG. 8A. FIG. 8A illustrates a schematic plan view of a display panel including the light emitting group EPG illustrated in FIG. 7. For convenience of description, only the emitting parts, the separator SPR, and the connection wirings are illustrated and other components are omitted. Hereinafter, an embodiment will be described in detail with reference to FIG. 8A and FIG. 8B. For example, the same reference numerals are given to the same components as those described with reference to FIG. 1 to FIG. 7, and redundant descriptions thereof will be omitted for descriptive convenience.

Referring to FIG. 8A, a display panel may include second electrodes EL2_R, EL2_G, and EL2_B partitioned by a separator SPR, and light emitting pattern layers EM_R, EM_G, EM_B1, and EM_B2 disposed in a region partitioned by the separator SPR and respectively overlapping the second electrodes EL2_R, EL2_G, and EL2_B. Each of the light emitting pattern layers EM_R, EM_G, EM_B1, and EM_B2 may correspond to the emitting layer EML (see FIG. 5A). For example, among the light emitting pattern layers EM_R, EM_G, EM_B1, and EM_B2, third emitting pattern layers EM_B1 and EM_B2 forming a third light emitting device may include two pattern layers spaced apart from each other in the second direction DR2. However, this is an example, and the third light emitting pattern layers EM_B1 and EM_B2 may be provided as a single pattern layer, and are not limited to any one embodiment.

As described above, emission connection parts of a first row CE1R, CE1G, CE1B, CE2R, CE2G, CE2B, CE3R, CE3G, CE3B, CE4R, CE4G, CE4B, CE5R, CE5G, and CE5B may be divided and disposed on an upper side or a lower side of the corresponding row, and driver connection parts CD1R, CD1G, CD1B, CD2R, CD2G, and CD2B may be disposed in a line along the first direction DR1 at an intermediate position of the corresponding row. In the same manner, emission connection parts of a second row CE6R, CE6G, CE6B, CE7R, CE7G, CE7B, CE8R, CE8G, CE8B, CE9R, CE9G, CE9B, CE10R, CE10G, and CE10B may be divided and disposed on an upper side or a lower side of the corresponding row, and driver connection parts CD6R, CD6G, CD6B, CD7R, CD7G, and CD7B may be disposed in a line along the first direction DR1 at an intermediate position of the corresponding row.

Emitting parts overlapping the driver connection parts CD1R, CD1G, CD1B, CD2R, CD2G, CD2B, CD6R, CD6G, CD6B, CD7R, CD7G, and CD7B may be emitting parts disposed in the first region AA1 (see FIG. 3B), and emitting parts not overlapping the driver connection parts CD1R, CD1G, CD1B, CD2R, CD2G, CD2B, CD6R, CD6G, CD6B, CD7R, CD7G, and CD7B may be emitting parts disposed in the second region AA2 (see FIG. 3B). As a light emitting device and a pixel circuit are disposed at a non-overlapping position in a plan view, the light emitting device and the pixel circuit may be electrically connected through connection wirings.

Some connection wirings CN1R, CN2R, CN2B, CN3R, CN4R, CN4B, and CN5R of connection wirings CN1R, CN1G, CN1B, CN2R, CN2G, CN2B, CN3R, CN3G, CN3B, CN4R, CN4G, CN4B, CN5R, CN5G, and CN5B disposed in the first row may extend to an upper side of the driver connection parts CD1R, CD1G, CD1B, CD2R, CD2G, and CD2B and provide emission connection parts CE1R, CE2R, CE2B, CE3R, CE4R, CE4B, and CE5R disposed on the upper side. Other connection wirings CN1G, CN1B, CN2G, CN3G, CN3B, CN4G, CN5G, and CN5B of the connection wirings CN1R, CN1G, CN1B, CN2R, CN2G, CN2B, CN3R, CN3G, CN3B, CN4R, CN4G, CN4B, CN5R, CN5G, and CN5B disposed in the first row may extend to a lower side of the driver connection parts CD1R, CD1G, CD1B, CD2R, CD2G, and CD2B and provide emission connection parts CE1G, CE1B, CE2G, CE3G, CE3B, CD4G, CD5G, and CD5B disposed on the lower side.

Some connection wirings CN6R, CN6B, CN7R, CN8R, CN8B, CN9R, CN10R, and CN10B of connection wirings CN6R, CN6G, CN6B, CN7R, CN7G, CN7B, CN8R, CN8G, CN8B, CN9R, CN9G, CN9B, CN10R, CN10G, and CN10B disposed in the second row may extend to an upper side of the driver connection parts CD6R, CD6G, CD6B, CD7R, CD7G, and CD7B and provide emission connection parts CE6R, CE6B, CE7R, CE8R, CE8B, CE9R, CE10R, and CE10B disposed on the upper side. Other connection wirings CN6G, CN7G, CN7B, CN8G, CN9G, CN9B, and CN10G of the connection wirings CN6R, CN6G, CN6B, CN7R, CN7G, CN7B, CN8R, CN8G, CN8B, CN9R, CN9G, CN9B, CN10R, CN10G, and CN10B disposed in the second row may extend to a lower side of the driver connection parts CD6R, CD6G, CD6B, CD7R, CD7G, and CD7B and provide emission connection parts CE6G, CE7G, CE7B, CE8G, CE9G, CE9B, and CE10G disposed on the lower side.

Looking in more detail with reference to FIG. 8B, the connection wirings CN1R, CN2R, CN2B, CN3R, CN4R, CN4B, and CN5R extending to the upper side of the driver connection parts CD1R, CD1G, CD1B, CD2R, CD2G, and CD2B may be disposed in a space ERn between the driver connection parts CD1R, CD1G, CD1B, CD2R, CD2G, and CD2B and the upper emission connection parts CE4R, CE4B, and CE5R. In the same manner, the connection wirings CN1G, CN1B, CN2G, CN3G, CN3B, CN4G, CN5G, and CN5B extending to the lower side of the driver connection parts CD1R, CD1G, CD1B, CD2R, CD2G, and CD2B may be disposed in a space ERn+1 between the driver connection parts CD1R, CD1G, CD1B, CD2R, CD2G, and CD2B and the lower emission connection parts CE5G and CE5B.

According to an embodiment, the order (or arrangement order) in which the driver connection parts CD1R, CD1G, CD1B, CD2R, CD2G, and CD2B are arranged along the first direction DR1 may be set to be the same as the order (or arrangement order) in which the emission connection parts CE1R, CE1G, CE1B, CE2R, CE2G, and CE2B connected to emitting parts are arranged. Accordingly, in each of the spaces ERn and ERn+1, five or fewer number of connection wirings may be arranged in consideration of the pitch and line widths of connection wirings. Looking at a ZZ′ region in which the bending of connection wirings occurs many times, only five connection wirings CN2G, CN3G, CN3B, CN4G, and CN5G may be disposed between the driver connection part CD2G and the emission connection part CE5B.

This may be because the order (or arrangement order) of the two driver connection parts CD2G and CD2R is designed to be the same as the order (or arrangement order) in which the emission connection parts CE2G and CE2R are arranged. According to an embodiment, by designing the order (or arrangement order) in which the driver connection parts CD1R, CD1G, CD1B, CD2R, CD2G, and CD2B are arranged along the first direction DR1 to be the same as the order (or arrangement order) in which the emission connection parts CE1R, CE1G, CE1B, CE2R, CE2G, and CE2B connected to emitting parts are arranged, the occurrence of bottlenecks between connection wirings may be reduced or minimized. Accordingly, a denser line design may be implemented within the same region, and interference between lines may be reduced although the length of a connection wiring is increased. Accordingly, a separation distance of a light emitting device connected to a driver connection part may be increased, and a display panel having a substantially increased display region and a reduced bezel region may be provided.

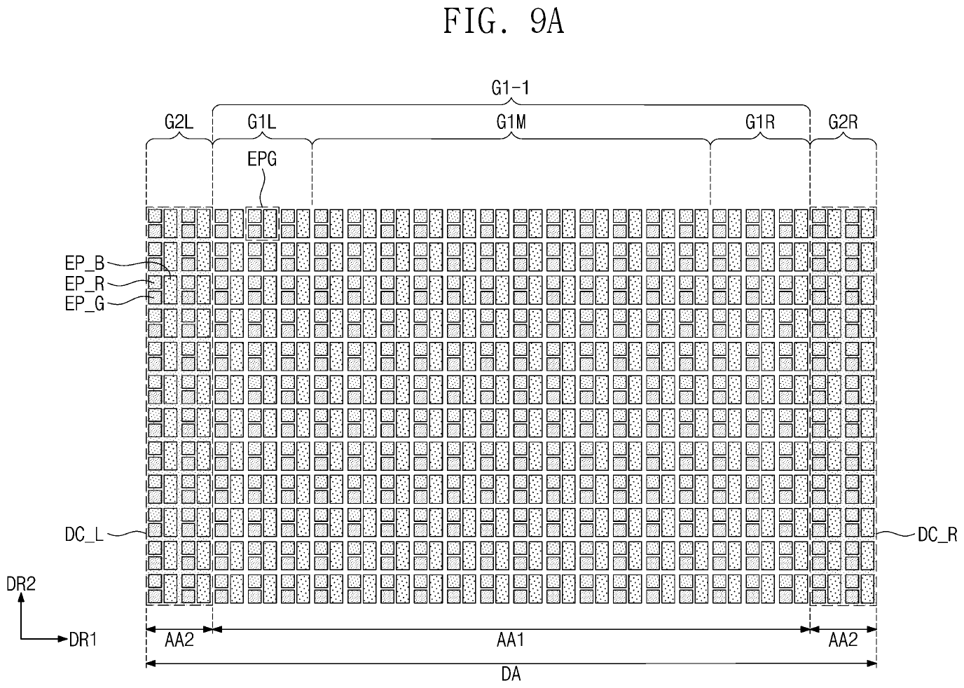

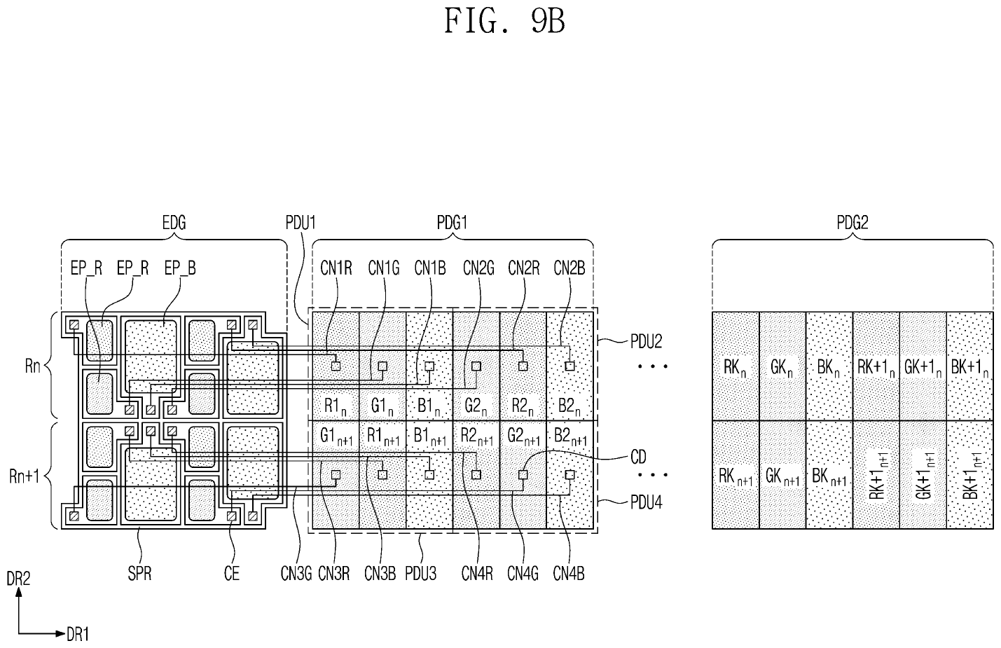

FIG. 9A is a schematic plan view of a display panel according to an embodiment. FIG. 9B is a drawing illustrating a portion of the display panel illustrated in FIG. 9A. Hereinafter, an embodiment will be described with reference to FIG. 9A and FIG. 9B. For example, the same reference numerals are given to the same components as those described with reference to FIG. 1 to FIG. 8B, and redundant descriptions thereof will be omitted for descriptive convenience.

As illustrated in FIG. 9A, a main group G1-1 disposed in a first region AA1 may include sub-groups G1M, G1L, and G1R. The sub-groups G1M, G1L, and G1R may include first to third sub-groups G1M, G1L, and G1R. A light emitting group EPG may have the same shape and arrangement in the main group G1-1 or in first and second groups G2L and G2R.

However, as illustrated in FIG. 8B, pixel circuits may be designed differently for each group. For example, a pixel circuit group PDG1 (hereinafter, a first pixel driving group) connected to emitting parts disposed in the second and third sub-groups G1L or G1R or in the first and second groups G2L and G2R and a pixel circuit group PDG2 (hereinafter, a second pixel driving group) connected to the first sub-group G1M may be designed to have different arrangements from each other.

The first pixel driving group PDG1 may be connected to the light emitting group EPG through connection wirings CN1R, CN1G, CN1B, CN2G, CN2R, CN2B, CN3G, CN3R, CN3B, CN4R, CN4G, and CN4B. Therefore, in the second and third sub-groups GIL and G1R or the first and second groups G2L and G2R which do not overlap or are displaced from a corresponding pixel driver in a plan view, driver connection parts CD may be arranged to correspond to the order (or arrangement order) in which emission connection parts CE of the light emitting group EPG are arranged in the first direction DR1. Accordingly, bottlenecks between the connection wirings CN1R, CN1G, CN1B, CN2G, CN2R, CN2B, CN3G, CN3R, CN3B, CN4R, CN4G, and CN4B may be reduced, and a dense line design may be implemented within a predetermined region.

For example, the second pixel driving group PDG2 may include emitting parts disposed at positions overlapping a corresponding pixel circuit in a plan view, so that a second electrode EL2 (see FIG. 5A) and a connection transistor TR (see FIG. 5A) may be connected without a separate connection wiring or connection may be achieved even with a connection wiring relatively shorter than a connection wiring disposed in the first pixel driving group PDG1. Therefore, the arrangement of pixel circuits of the second pixel driving group PDG2 may be designed independently from the first pixel driving group PDG1. In an embodiment, by designing the same for all regions of the first sub-group G1M, the designing may be simplified.

According to an embodiment, a display panel capable of extending a display region and having a narrow bezel may be provided.

For example, according to an embodiment, a circuit design plan capable of preventing electrical interference between lines while having an extended display region may be provided.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising:
a first emitting part, a second emitting part, and a third emitting part arranged along a first direction;
a first transistor, a second transistor, and a third transistor spaced apart from the first, second, and third emitting parts in the first direction, and arranged along the first direction; and
a first connection wiring, a second connection wiring, and a third connection wiring each extending along the first direction and connecting the first, second, and third emitting parts to the first, second, and third transistors, wherein
the first, second, and third connection wirings include:
a first emission connection part, a second emission connection part, and a third emission connection part each connected to a corresponding emitting part among the first, second, and third emitting parts; and
a first driver connection part, a second driver connection part, and a third driver connection part each connected to a corresponding transistor among the first, second, and third transistors, and
an arrangement order of the first, second, and third emission connection parts arranged along the first direction and an arrangement order of the first, second, and third driver connection parts arranged along the first direction are same as each other.

2. The display panel of claim 1, wherein the first, second, and third emission connection parts are arranged along the first direction.

3. The display panel of claim 2, further comprising:
a fourth emitting part, a fifth emitting part, and a sixth emitting part different from the first, second, and third emitting parts;
a fourth transistor, a fifth transistor, and a sixth transistor different from the first, second, and third transistors;
a fourth connection wiring, a fifth connection wiring, and a sixth connection wiring spaced apart from the first, second, and third connection wirings in a plan view, and respectively connecting the fourth, fifth, and sixth emitting parts to the fourth, fifth, and sixth transistors, wherein
the fourth, fifth, and sixth connection wirings include:
a fourth emission connection part, a fifth emission connection part, and a sixth emission connection part respectively connected to the fourth, fifth, and sixth emitting parts; and
a fourth driver connection part, a fifth driver connection part, and a sixth driver connection part respectively connected to the fourth, fifth, and sixth transistors, and
the fourth, fifth, and sixth emission connection parts are arranged along the first direction.

4. The display panel of claim 3, wherein:
the fourth, fifth, and sixth transistors are spaced apart from the first, second, and third transistors in the first direction; and
the first, second, and third emission connection parts and the fourth, fifth, and sixth emission connection parts do not overlap each other in the first direction.

5. The display panel of claim 4, wherein
the first, second, and third driver connection parts are arranged along the first direction, and
the fourth, fifth, and sixth driver connection parts are arranged along the first direction.

6. The display panel of claim 5, wherein among the first, second, third, fourth, fifth, and sixth connection wirings, the first, second, and third connection wirings extend in an opposite direction with respect to the fourth, fifth, and sixth connection wirings and the fourth, fifth, and sixth driver connection parts.

7. The display panel of claim 3, wherein an arrangement order of the first, second, third, fourth, fifth, and sixth emission connection parts arranged in the first direction and an arrangement order of the first, second, third, fourth, fifth, and sixth transistors arranged in the first direction are same as each other.

8. The display panel of claim 3, wherein the first, second, and third driver connection parts are respectively spaced apart from the fourth, fifth, and sixth driver connection parts in a second direction intersecting the first direction.

9. The display panel of claim 8, wherein light emitted by the first light emitting part and light emitted by the fourth light emitting part have different colors from each other.

10. The display panel of claim 9, wherein an arrangement order of the first, second, and third emitting parts and an arrangement order of the fourth, fifth, and sixth emitting parts are same as each other.

11. The display panel of claim 9, further comprising:
a seventh emitting part, an eighth emitting part, and a ninth emitting part spaced apart from the first, second, and third emitting parts in the first direction;
a tenth emitting part, an eleventh emitting part, and a twelfth emitting part spaced apart from the fourth, fifth, and sixth emitting parts in the first direction and respectively spaced apart from the seventh, eighth, and ninth emitting parts in the second direction;
a seventh transistor, an eighth transistor, and a ninth transistor overlapping the seventh, eighth, and ninth emitting parts in a plan view, respectively connected to the seventh, eighth, and ninth emitting parts, and arranged along the first direction; and
a tenth transistor, an eleventh transistor, and a twelfth transistor overlapping the tenth, eleventh, and twelfth emitting parts in a plan view, respectively connected to the tenth, eleventh, and twelfth emitting parts, and arranged along the first direction,
wherein the seventh emitting part and the tenth emitting part emit a same color light.

12. The display panel of claim 1, further comprising:
a driving circuit overlapping the first, second, and third emitting parts in a plan view, the driving circuit that provides an electrical signal to each of the first, second, and third emitting parts,
wherein the first, second, and third transistors are spaced apart from the driving circuit.

13. The display panel of claim 1, wherein
each of the first, second, and third emitting parts comprises:
a first electrode,
a second electrode disposed on the first electrode, and
an emission connection part, and
the emission connection part is connected to the second electrode.

14. The display panel of claim 13, wherein:
the second electrodes of the respective first, second, and third emitting parts are separated from each other; and
each of the second electrodes is a cathode of each of the first, second, and third emitting parts.

15. The display panel of claim 1, wherein each of the first, second, and third transistors is an N-type transistor.

16. A display panel comprising:
a plurality of pixels including first group pixels and second group pixels, the first and second group pixels including:
emitting parts, and
driving transistors connected to the emitting parts; and
a driving circuit that provides an electrical signal to each of the plurality of pixels, and overlaps at least some of the emitting parts of the plurality of pixels in a plan view, wherein
the emitting parts of the first group pixels overlap the driving circuit,
the emitting parts of the second group pixels are spaced apart from the driving circuit,
the first group pixels includes connection wirings, the connection wirings including:
emission connection parts connected to the emitting parts of the first group pixels, and
driver connection parts connected to the driving transistors of the first group pixels, and
an arrangement order of the driving transistors of the first group pixels arranged along a first direction and an arrangement order of the emission connection parts of the first group pixels arranged in the first direction are same as each other.

17. The display panel of claim 16, wherein each of the connection wirings of the first group pixels is disposed in a space between the emission connection parts of the first group pixels and the driver connection parts of the first group pixels.

18. The display panel of claim 16, wherein each of the connection wirings of the first group pixels has a multi-layered structure.

19. The display panel of claim 16, wherein
each of the emitting parts of the plurality of pixels comprises:
an anode,
a cathode disposed on the anode, and
an emitting part disposed between the anode and the cathode, and
each of the driving transistors of the plurality of pixels is connected to the cathode.

20. The display panel of claim 16, wherein the arrangement order of the driving transistors of the first group pixels arranged in the first direction is different from each other in adjacent rows.

21. The display panel of claim 16, wherein an arrangement order of the driving transistors of the second group pixels arranged in the first direction is different from the arrangement order of the driving transistors of the first group pixels arranged in the first direction.
